(19) United States
(12) Patent Application Publication
(10) Pub. No.: US 2024/0396300 A1
(43) Pub. Date: Nov. 28, 2024

(54) METHOD AND SYSTEM FOR MANUFACTURING AN ARRAY OF GROUP III-NITRIDE NANOWIRES, AND SEMICONDUCTOR SUBSTRATE

(71) Applicant: THE ROYAL INSTITUTION FOR THE ADVANCEMENT OF LEARNING/MCGILL UNIVERSITY, Montréal (CA)

(72) Inventors: Songrui ZHAO, Brossard (CA); Mohammad Fazel VAFADAR, Montréal (CA)

(21) Appl. No.: 18/660,805

(22) Filed: May 10, 2024

(30) Foreign Application Priority Data
May 12, 2023 (CA) 3199428

(51) Int. Cl. H01S 5/183; H01S 5/323

(52) U.S. Cl. CPC H01S 5/183; H01S 5/32341

(57) ABSTRACT

There is described a method of manufacturing an array of gallium nitride (GaN) nanowires via selective area growth. The method generally has: mounting a substrate to a substrate holder face exposed within a growth cavity, the substrate having a base layer and a mask covering the base layer, the mask having a plurality of apertures spaced apart from one another and exposing the base layer thereunder; while heating the growth cavity at a given surface temperature ranging between about 650° C. and 750° C. when measured on a side of the substrate holder face to which the substrate is mounted, directing gallium (Ga) and nitrogen (N) atoms towards the selective area growth mask at a gallium growth rate below about 10 nm/min and a nitrogen growth rate below 5 nm/min, respectively, said heating and said directing selectively growing the GaN nanowires at corresponding ones of the apertures.

### FIELD

The improvements relate to semiconductor substrates and more particularly relate to semiconductor substrates including arrays of nanowires.

### BACKGROUND

In electronics, a substrate generally consists of a thin wafer of semiconductor material on which electronic components are built using one or more microfabrication steps, such as doping, ion implantation, etching, thin-film deposition of various materials, and photolithographic patterning, to name a few exemplary steps. In some circumstances, the electronic component deposited, grown or otherwise mounted to the semiconductor substrate can be provided in the form of an array of nanowires. As these nanowires have a thickness constrained to tens of nanometers or less, and an unconstrained length, they can act as a one-dimensional (1D) material having interesting quantum mechanical properties that are not seen in bulk or three-dimensional (3D) materials. These desirable properties come from electrons being laterally confined within the nanowire and occupying energy levels that are different from the traditional continuum of energy levels or bands found in bulk materials. There exist different types of nanowires, however interest towards gallium nitride (GaN) nanowires have developed as this material has a direct band gap of 3.4 eV at room temperature, which can be particularly useful in applications including, but not limited to, photovoltaic devices, field effect transistors, light emitting diodes, lasers, to name a few examples. Although existing group III-nitride nanowire manufacturing processes are satisfactory to a certain degree, there always remain rooms for improvement.

### SUMMARY

Successful synthesis of group III-nitride nanowire such as GaN nanowires has been demonstrated via various methods including chemical vapor deposition, laser ablation, metalorganic chemical vapor deposition, molecular beam epitaxy, and hydride vapour phase epitaxy. However, existing GaN nanowire manufacturing processes have yet to achieve nanowires of uniform geometries.

The present disclosure presents a method of manufacturing an array of GaN nanowires onto a semiconductor substrate in a way which produces nanowires that are substantially more uniform than what can be achieved using existing techniques. As described below, the proposed method of manufacturing involves the use of a molecular beam epitaxy growth chamber in which the growth temperature is cooler than the growth temperature generally used to grow GaN nanowires using existing selective area growth (SAG) techniques. As the growth temperature is cooler, the gallium (Ga) and nitrogen (N) growth rates can be proportionally lower thus requiring a lower amount of gallium and nitride, which can in turn be more cost and material efficient. This can also alleviate the manufacturing process as the replenishing of the gallium and nitrogen sources can be performed at a lower frequency.

It was found that by manufacturing the GaN nanowires at a lower temperature, with lower gallium and nitrogen growth rates, the GaN nanowires grow into nanowires of better uniformity in terms of length, thickness, shape, or a combination thereof. In some circumstances, the GaN nanowires can develop tips having flat top facets which was found to be particularly convenient as typical post-growth polishing steps, which are generally required as conventionally produced GaN nanowires have pyramid-shaped tips, can be omitted. Omitting such polishing steps can reduce the costs associated with the overall nanowire manufacturing process. Moreover, other materials can be deposited onto the flat top facets of the tips of the GaN nanowires directly after their growth, without having to open a hatch of the growth chamber. Furthermore, when the proposed array of uniform GaN nanowires is used as resonant cavity of an optical emitting device, the uniformity of the GaN nanowires can yield an enhanced Q-factor from which lasing operation can be observed at low lasing threshold power density thresholds, for instance below 10 kW/cm².

In accordance with a first aspect of the present disclosure, there is provided a method of manufacturing an array of gallium nitride (GaN) nanowires via selective area growth, the method comprising: mounting a substrate to a substrate holder face exposed within a growth cavity, the substrate having a base layer and a selective area growth mask covering the base layer, the selective area growth mask having a plurality of apertures spaced apart from one another and exposing the base layer thereunder; while heating the growth cavity at a given surface temperature, the given surface temperature ranging between about 650° C. and 750° C. when measured on a side of the substrate holder face to which the substrate is mounted, directing gallium (Ga) and nitrogen (N) atoms towards the selective area growth mask at a gallium growth rate below about 10 nm/min and a nitrogen growth rate below 5 nm/min, respectively, said heating and said directing selectively growing the GaN nanowires of the array at corresponding ones of the plurality of apertures.

Further in accordance with the first aspect of the present disclosure, the given surface temperature can for example preferably range between about 710° C. and 730° C., and most preferably is about 720° C.

Still further in accordance with the first aspect of the present disclosure, the gallium growth rate can for example range between 1 and 10 nm/min, preferably between 2 and 8 nm/min and most preferably between 1.5 and 5 nm/min.

Still further in accordance with the first aspect of the present disclosure, the nitrogen growth rate can for example range between 2 and 5 nm/min, preferably between 3 and 4 nm/min.

Still further in accordance with the first aspect of the present disclosure, the base layer can for example be a GaN layer.

Still further in accordance with the first aspect of the present disclosure, the growing can for example include the plurality of GaN nanowires growing into a relatively uniform geometry.

Still further in accordance with the first aspect of the present disclosure, the plurality of GaN nanowires can for example have at least one of a uniform length, a uniform cross-sectional shape, a uniform thickness and a uniform tip shape.

Still further in accordance with the first aspect of the present disclosure, the GaN nanowires can for example have a base at a corresponding one of the plurality of apertures, an elongated body extending transversally to the substrate and a tip, at least some of the tips of the plurality of GaN nanowires can for example end in a planar top facet parallel to the substrate.

Still further in accordance with the first aspect of the present disclosure, the at least some of the tips of the plurality of GaN nanowires can for example end in a uniform wurtzite-like structure.

Still further in accordance with the first aspect of the present disclosure, the plurality of apertures of the selective area growth mask can for example have a hexagonal shape.

Still further in accordance with the first aspect of the present disclosure, the plurality of apertures have a dimension d of about 330 nm and a lattice parameter a of about 450 nm.

Still further in accordance with the first aspect of the present disclosure, the selective area growth mask can for example include one of silicon nitride, titanium, and silicon dioxide, and the base layer can for example include a GaN-based layer.

It is understood that although GaN nanowires are discussed at great length in this disclosure, the array of nanowires can equivalently be made of any group III-nitride semiconductor material(s) including, but not limited to, gallium nitride (GaN), aluminum gallium nitride (AlGaN), indium gallium nitride (InGaN), or a combination thereof, depending on the embodiment.

In accordance with a second aspect of the present disclosure, there is provided a semiconductor substrate comprising: a base layer; a mask layer covering the base layer, the mask layer having a plurality of apertures spaced apart from one another; a plurality of group III-nitride nanowires extending away from the plurality of apertures, the group III-nitride nanowires having a base at a corresponding one of the plurality of apertures, an elongated body extending transversally to the base layer and a tip, the plurality of group III-nitride nanowires having at least one of a uniform geometry, a uniform length, a uniform cross-sectional shape, a uniform thickness and a uniform tip shape.

Further in accordance with the second aspect of the present disclosure, at least some of the tips of the plurality of group III-nitride nanowires can for example end in a planar top facet parallel to the substrate.

Still further in accordance with the second aspect of the present disclosure, at least some of the tips of the plurality of group III-nitride nanowires can for example end in a uniform wurtzite-like structure.

Still further in accordance with the second aspect of the present disclosure, the mask layer can for example include one of silicon nitride, titanium, and silicon dioxide.

Still further in accordance with the second aspect of the present disclosure, the semiconductor substrate can for example be part of an optical emitting device which when the plurality of group III-nitride nanowires are electrically pumped using a current greater than a current threshold, the optical emitting device generates a laser signal generally perpendicularly to the semiconductor substrate.

Still further in accordance with the second aspect of the present disclosure, the semiconductor substrate can for example further comprise a graphene electrode electrically connected to the tips of the plurality of group III-nitride nanowires, the current applied at least partially via the graphene electrode.

Still further in accordance with the second aspect of the present disclosure, the laser signal can for example include optical energy distributed within an ultraviolet range of the electromagnetic spectrum.

Still further in accordance with the second aspect of the present disclosure, the optical emitting device can for example have a lasing threshold power density threshold below 10 kW/cm².

Still further in accordance with the second aspect of the present disclosure, the group III-nitride nanowires can for example include one or more of the following group III-nitride semiconductor materials: gallium nitride (GaN), aluminum gallium nitride (AlGaN), and indium gallium nitride (InGaN).

In accordance with a third aspect of the present disclosure, there is provided a system for manufacturing an array of group III-nitride nanowires via selective area growth, the system comprising: a growth chamber defining a growth cavity; a substrate holder having a substrate holder face exposed within the growth cavity, the substrate holder face having a substrate removably mounted thereto, the substrate having a base layer and a selective area growth mask covering the base layer and facing away from the base layer, the selective area growth mask having a plurality of apertures spaced apart from one another and exposing the base layer thereunder; a heating element heating an immediate environment of the substrate to a given surface temperature; a group III element source mounted at a first port of the growth chamber, the group III element source directing group III element (e.g., In, Ga, Al) atoms towards the selective area growth mask; and a nitrogen source mounted at a second port of the growth chamber, the nitrogen source directing nitrogen (N) atoms towards the selective area growth mask.

Further in accordance with the third aspect of the present disclosure, the system can for example further comprise a temperature sensor measuring the given surface temperature of the immediate environment of the substrate.

Still further in accordance with the third aspect of the present disclosure, the system can for example further comprise a controller communicatively coupled to the heating element and the temperature sensor, the controller having a processor and a non-transitory memory having stored thereon instructions that when executed by the processor perform the step of: operating the heating element based on the temperature readings of the temperature sensor.

Still further in accordance with the third aspect of the present disclosure, said directing the nitrogen atoms towards the selective area growth mask is performed at a nitrogen growth rate below 5 nm/min.

Still further in accordance with the third aspect of the present disclosure, said directing the group III element atoms towards the selective area growth mask is performed at a given growth rate below 10 nm/min.

In accordance with a fourth aspect of the present disclosure, there is provided a method of manufacturing a surface-emitting lasing device having an array of III-nitride nanowires, the method comprising: selecting a lasing wavelength ranging between about 200 nm and 2 μm, the lasing wavelength characterizing lasing emission occurring upon pumping of the surface-emitting lasing device; determining manufacturing parameters based on the lasing wavelength, the manufacturing parameters including: a semiconductor material composition, a lattice constant defining the array, a nanowire geometry and a nanowire dimension; forming a growth mask onto an a base layer of a substrate, the growth mask having a plurality of apertures sized and shaped according to the lattice constant, the nanowire geometry and the nanowire dimension; and while heating the substrate at a given surface temperature, directing semiconductor material molecules according to the semiconductor material composition towards the selective area growth mask, said heating and said directing selectively growing the III-nitride nanowires of the array at corresponding ones of the plurality of apertures.

Still further in accordance with the fourth aspect of the present disclosure, the group III-nitride nanowires can for example include one or more of the following group III-nitride semiconductor materials: gallium nitride (GaN), aluminum gallium nitride (AlGaN), and indium gallium nitride (InGaN).

Still further in accordance with the fourth aspect of the present disclosure, the pumping can for example be an optical pumping or an electrical pumping.

Many further features and combinations thereof concerning the present improvements will appear to those skilled in the art following a reading of the instant disclosure.

### DESCRIPTION OF THE FIGURES

In the figures,

FIG. 1 is a schematic view of an example of a system for manufacturing an array of gallium nitride (GaN) nanowires via selective area growth (SAG), in accordance with one or more embodiments;

FIG. 2A is an oblique view of an example of a semiconductor substrate having a base layer and a SAG mask covering the base layer, in accordance with one or more embodiments;

FIG. 2B is an oblique view showing an exemplary GaN nanowire growing from one aperture of the SAG mask of FIG. 2A, in accordance with one or more embodiments;

FIG. 2C is side elevation view of the semiconductor substrate of FIG. 2A, showing a fully grown array of GaN nanowires, in accordance with one or more embodiments;

FIG. 3 is a flow chart of an example method of manufacturing an array of GaN nanowires via SAG, in accordance with one or more embodiments;

FIG. 4A is an example of a GaN-on-sapphire substrate having a GaN layer and a SAG mask covering the GaN layer, in accordance with one or more embodiments;

FIG. 4B is a scanning electron microscope (SEM) image showing apertures of the SAG mask of FIG. 4A, in accordance with one or more embodiments;

FIG. 4C is an oblique view of an array of GaN nanowires grown on the GaN-on-sapphire substrate of FIG. 4A, in accordance with one or more embodiments;

FIGS. 5A to 5F are SEM images showing GaN nanowires grown using different surface temperatures T_{sub} and nitrogen growth rates N_{flux} combinations, in accordance with one or more embodiments;

FIG. 6 is a graph showing lateral (filled symbols) and vertical (open symbols) growth rates versus surface temperature (T_{sub}) for different nitrogen growth rates N_{flux} (the values are labeled in the plot), and also showing regimes for thin film growth and no growth, in accordance with one or more embodiments;

FIGS. 7A to 7F are SEM images showing GaN nanowires grown using different design patterns but with the same growth conditions, in accordance with one or more embodiments;

FIG. 8A is a graph showing lateral (filled symbols) and vertical (open symbols) growth rates versus lattice constant a (and with an aperture diameter of d=100 nm), in accordance with one or more embodiments;

FIG. 8B is a graph showing lateral (filled symbols) and vertical (open symbols) growth rates versus aperture diameter d (and with a lattice constant of a=450 nm), in accordance with one or more embodiments;

FIG. 9 is a graph showing top facet length L_{c} versus aperture diameter d under different lattice constant a, with an insert showing the schematic of several planes (m, a, r, and c planes) of the resulting wurtzite-like nanowire structure, in accordance with one or more embodiments;

FIG. 10A is an oblique view of an optical emitting device incorporating a semiconductor substrate having an array of GaN nanowires, with an inset showing in-plane light propagation and diffraction normal to the plane, in accordance with one or more embodiments;

FIG. 10B is a top plan view of the array of GaN nanowires of FIG. 10A, in accordance with one or more embodiments;

FIG. 10C is a graph showing photonic bands of the array of GaN nanowires of FIG. 10A with an aperture diameter of a=200 nm and d_{NW}=173 nm, with the dashed line indicating the reduced frequency corresponds to λ=367 nm, in accordance with one or more embodiments;

FIG. 10D is a graph showing the electric field profile of the band edge mode of the array of GaN nanowires of FIG. 10A calculated by the 3D finite-difference time-domain (FDTD) method, in accordance with one or more embodiments;

FIG. 11A is a SEM image of the lasing array of GaN nanowires of FIG. 10A, in accordance with one or more embodiments;

FIG. 11B is a graph showing the room temperature (RT) photoluminescence (PL) spectra of the lasing and non-lasing arrays of GaN nanowires, in accordance with one or more embodiments;

FIG. 12A is a graph showing the room temperature photoluminescence spectra of the lasing array of GaN nanowires of FIG. 10A under different excitation powers, in accordance with one or more embodiments;

FIG. 12B is a graph showing the room temperature photoluminescence intensity versus the power density in a linear scale, in accordance with one or more embodiments;

FIG. 12B is a graph showing the room temperature photoluminescence intensity versus the power density in a logarithmic scale, in accordance with one or more embodiments;

FIG. 12D is a graph showing linewidth (open symbols) and the room temperature photoluminescence peak position (filled symbols) versus the power density, in accordance with one or more embodiments;

FIG. 13A is a schematic view of an example setup for the in-plane polarization measurement at Γ point, in accordance with one or more embodiments;

FIG. 13B is a graph showing polarized light emission from the lasing array of GaN nanowires of FIG. 10A at φ=0° and φ=90°, in accordance with one or more embodiments;

FIG. 13C is a polar plot showing the room temperature photoluminescence intensity measured from the lasing array of GaN nanowires of FIG. 10A at different in-plane angle φ, when the excitation density was 63.5 kW/cm², in accordance with one or more embodiments;

FIG. 14 is a graph showing a comparison of the lasing threshold power density (Pₜₕ) for existing UV lasers versus the lasing array of GaN nanowires of FIG. 10A, in accordance with one or more embodiments;

FIG. 15A is a graph showing the current density as a function of excitation voltage for an optical emitting device having a graphene electrode deposited on the array of GaN nanowires, in accordance with one or more embodiments;

FIG. 15B is a graph showing the emission spectra under different injection currents where a spectral narrowing suggests light amplification, which is more apparent from the inset plotting the linewidth of the spectra as a function of the injection current, in accordance with one or more embodiments; and

FIG. 16 is a schematic view of an example framework for achieving surface-emitting lasers with on demand lasing wavelength, in accordance with one or more embodiments;

FIG. 17A is a tilted-view SEM image of a GaN nanowire array with triangular lattice with circular openings, showing an inset defining the definition of lattice constant “a,” in accordance with one or more embodiments;

FIG. 17B is a tilted-view SEM image of a GaN nanowire array with triangular lattice with hexagonal openings, in accordance with one or more embodiments;

FIG. 17C is a tilted-view SEM image of a GaN nanowire array with square lattice with circular openings, in accordance with one or more embodiments;

FIG. 17D is a tilted-view SEM image of a AlGaN/GaN nanowire array on patterned substrates with a square lattice, in accordance with one or more embodiments;

FIG. 17E is a tilted-view SEM image of a GaN nanowire array on patterned substrates with a square lattice, in accordance with one or more embodiments;

FIG. 17F is a tilted-view SEM image of a InGaN/GaN nanowire array on patterned substrates with a square lattice, in accordance with one or more embodiments;

FIG. 17G is a graph showing RTPL spectra of various AlGaN, GaN, and InGaN nanowires emitting from 250 nm to 500 nm, in accordance with one or more embodiments;

FIG. 17H is a graph showing derived Al and In molar fraction of AlGaN and InGaN nanowires using Vegard's law, in accordance with one or more embodiments;

FIG. 18A is a schematic view of an example nanowire array having GaN/low In content InGaN epi-NPC using a square lattice, with two representative in-plane light propagation directions (Γ-X and Γ-M) labeled, in accordance with one or more embodiments;

FIG. 18B is a graph showing a RTPL spectra of the low In content InGaN of the nanowire array of FIG. 18A, in accordance with one or more embodiments;

FIG. 18C is a high-resolution TEM image of an individual GaN nanowire that forms GaN nanowire arrays, with inset showing a SAED pattern, in accordance with one or more embodiments;

FIG. 18D is a graph showing an example photonic band structure of an InGaN NPC with a=200 nm and dNW=187 nm, with the dotted line indicating a reduced frequency that corresponds to λ of around 378 nm, in accordance with one or more embodiments;

FIGS. 18E and 18F are graphs showing in-plane and out of plane electric field profile (|E|2) of the band edge mode calculated by the 3D FDTD method, respectively, in accordance with one or more embodiments;

FIG. 19A is an optical image of an example of an epi-NPC, in accordance with one or more embodiments;

FIG. 19B is a top view SEM image of the low In content InGaN nanowire arrays that form the epi-NPC from the boxed region of FIG. 19A, in accordance with one or more embodiments;

FIG. 19C is a graph showing light emission spectra of the InGaN epi-NPC under different excitation powers, in accordance with one or more embodiments;

FIG. 19D is a graph showing light intensity versus the excitation power density in a linear scale, with the inset showing the same plot but in a logarithmic scale, in accordance with one or more embodiments;

FIG. 19E is a graph showing light emission spectra of the optically pumped GaN and low In content InGaN epi-NPCs with different lattice constant a and nanowire diameter dNW, in accordance with one or more embodiments;

FIG. 19F is a graph showing band-edge modes at Γ points (as labeled in FIG. 18B) calculated by COMSOL for GaN and low In content InGaN, and the experimental data for the epi-NPCs with various a and dNW, with filled symbols denoting optical pumping (corresponding to FIG. 19E), and open symbol denoting electrical injection, in accordance with one or more embodiments;

FIG. 20A is a schematic view of an example of an electrically injected nanowire array, shown with a graphene electrode and tungsten probes for electrical injection, in accordance with one or more embodiments;

FIG. 20B is a high-magnification SEM image of the graphene electrode of FIG. 20A, in accordance with one or more embodiments;

FIG. 20C is a graph showing a Raman spectra of the graphene electrode and the substrate of the FIG. 20A but without graphene, in accordance with one or more embodiments;

FIG. 20D is a graph showing I-V characteristics of a typical device, in accordance with one or more embodiments;

FIG. 20E is a graph showing light emission spectra of the device under different injection currents, in accordance with one or more embodiments;

FIG. 20F is a graph showing EL emission spectral linewidth versus the injection current, in accordance with one or more embodiments; and

FIG. 21 is a block diagram of an example of a computer device of a controller such as the one used in the system of FIG. 1, in accordance with one or more embodiments.

### DETAILED DESCRIPTION

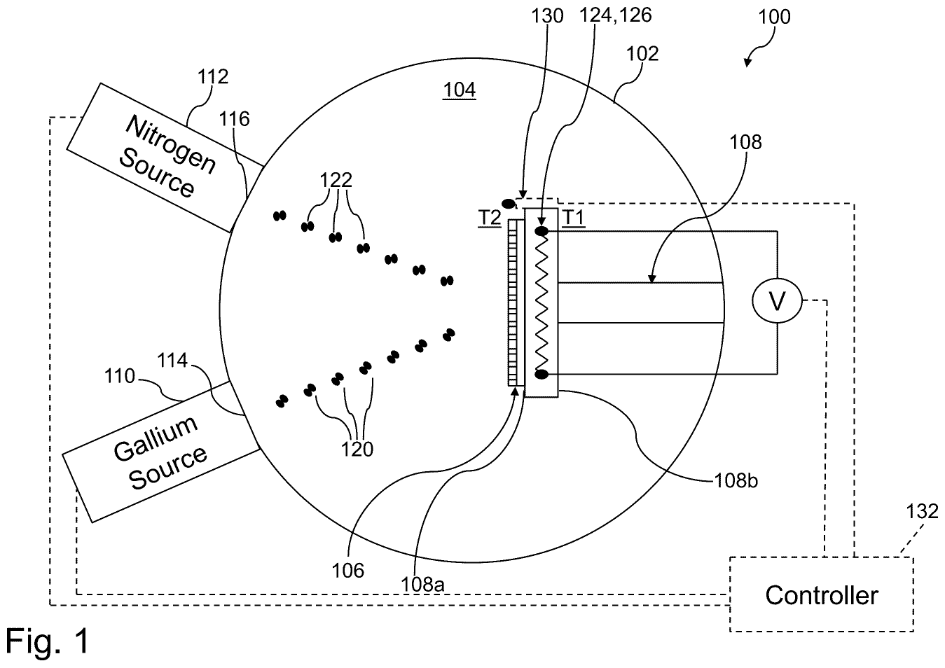

FIG. 1 shows an example of a system 100 for manufacturing an array of gallium nitride (GaN) nanowires via selective area growth. As depicted, the system 100 has a growth chamber 102 defining a growth cavity 104 where molecular beam epitaxy can be performed. In some embodiments, the growth chamber 102 is sized and shaped to receive semiconductor waters or substrates 106 of conventional sizes. However, the size of the growth chamber 102 can vary from one embodiment to another. The system 100 is provided with a substrate holder 108 having a substrate holder face 108a exposed within the growth cavity 104. The substrate holder 108 has a first end fixed inside the growth cavity 102 and a second end free-standing within the growth cavity 102. The substrate holder face 108a is part of the second, free-standing end of the substrate holder 108. In some embodiments, the substrate holder 108 may be rotatably mounted within the growth cavity 102 to allow rotation of the substrate holder face 108a during the manufacturing process.

As illustrated, the system 100 is provided with a gallium source 110 and a nitrogen source 112 which are both mounted to corresponding ports 114 and 116 of the growth chamber 102. During use, the gallium source 110 can be operated to direct gallium (Ga) atoms 120 towards the substrate holder face 108a at a gallium growth rate below about 10 nm/min. Moreover, the nitrogen source 112 can be operated to direct nitrogen (N) atoms 122 towards the substrate holder face 108a at a nitrogen growth rate below 5 nm/min. The gallium source 110 and the nitrogen source 112 can be operated independently from one another in some embodiments. Each source 110, 112 can include a molecular holder containing the corresponding chemical element in bulk, and a localized heating element heating the molecular holder until the atoms 120, 122 gain enough kinetic energy to sublimate and be ejected all around the molecular holder. In some embodiments, each source 110, 112 includes a pin hole or collimator ensuring that the atoms 120, 122 are beamed towards a desired target, e.g., the substrate holder face 108a. The growth rate can be controlled based on the composition of the corresponding chemical element in bulk or on how much energy is delivered via the localized heating element. Variants for the gallium and nitrogen sources 110 and 112 will appear to the person skilled in the art.

As depicted, the system 110 has a heating element 124. During use, the heating element 124 heats an immediate environment of the substrate holder face 108a to a given surface temperature ranging between about 650° C. and 750° C. In some embodiments, the heating element 124 includes a resistive wire 126 extending partially or wholly within the substrate holder 108. However, in some other embodiments, the heating element 124 can be separate from the substrate holder 108. It is noted that the temperature within the growth cavity 102 can vary depending of where the temperature measurement is made. For instance, in typical growth chambers, the temperature is usually measured behind the substrate holder face, at position T1. However, in this disclosure, the surface temperature referred to herein corresponds to the temperature measured in the immediate environment of the substrate holder face 108a, and more specifically, the surface temperature as would be measured proximate the substrate holder face 108a, near position T2. Regardless of where the temperature of the growth cavity 102 is measured, the range of temperature at which the growth occurs in this disclosure is such that it ranges between 650° C. and 750° C. proximate the substrate holder face 108a of the substrate holder 108, not at the opposite face 108b thereof.

A temperature sensor 130 can be provided to monitor the surface temperature during use. As shown, the temperature sensor 130 can be communicatively coupled to a controller 132 which is configured to control the operation of the gallium source 110, the nitrogen source 112 and the heating element 124. For instance, if the temperature readings show that the surface temperature is below the prescribed range, the controller 132 can operate the heating element 124 with more input energy to heat more. In contrast, if the temperature readings show that the surface temperature is greater than the prescribed range, the controller 132 can momentarily interrupt the operation of the heating element 124 for a given period of time. In some embodiments, the heating element 124 is operated such that the surface temperature oscillates or otherwise varies within the prescribed range. In some other embodiments, the heating element 124 is operated such that the surface temperature is constant throughout the manufacturing process.

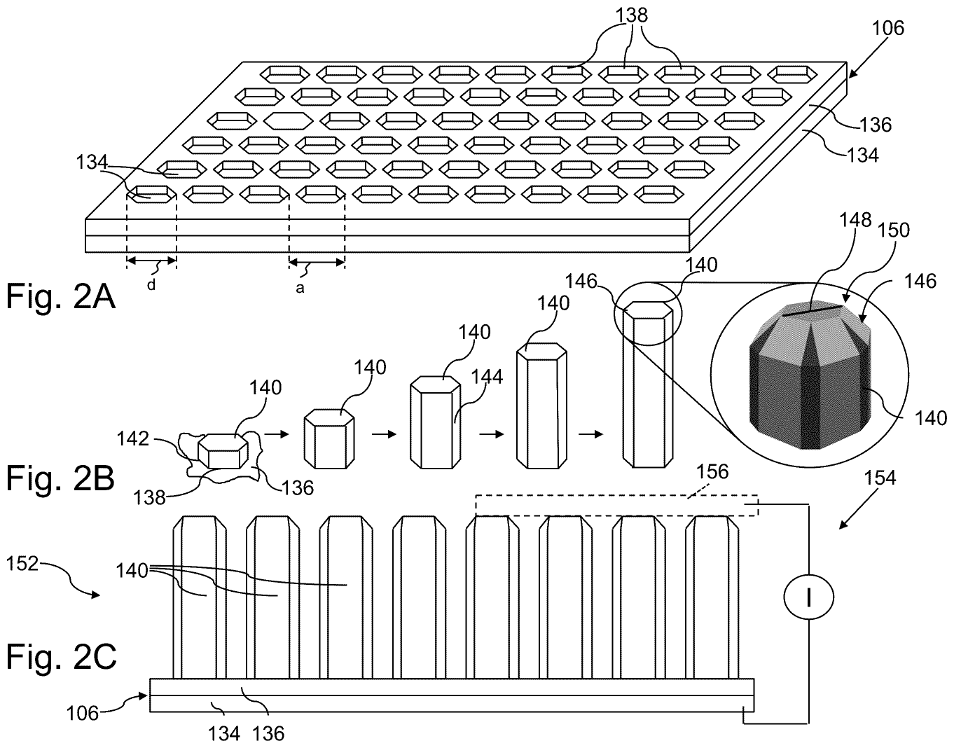

As shown, the substrate holder face 108a has a substrate 106 removably mounted thereto. As best shown in FIG. 2A, the substrate 106 has a base layer 134 and a selective area growth (SAG) mask 136 which covers the base layer 134 and which faces away from the base layer 134. It was found convenient to use a GaN-based layer or more specifically a GaN-on-sapphire layer as the base layer 134 in some circumstances. Examples of materials for the base layer 134 can include, but are not limited to, silicon, sapphire and the like. In some embodiments, the SAG mask 136 includes silicon nitride, titanium, or silicon dioxide, depending on the embodiment. As shown, the SAG mask 136 has a number of apertures 138 spaced apart from one another which expose the base layer 134 thereunder at corresponding locations. Although the illustrated apertures 138 have an hexagonal shape, the apertures 138 can have a triangular shape, a circular shape, an ovoid shape, a square shape, a pentagonal shape, or any other suitable polygonal shape. The dimension of the apertures 138 can be referred to the parameter d, which can correspond to a diameter of the apertures in embodiments where the apertures 138 are circular. In other embodiments, the dimension d merely refers to a cross-sectional dimension of the apertures 138. Moreover, the distance between each of the apertures 138 can be referred to the parameter a, which is often referred to as the lattice parameter.

When the Ga and N atoms are directed towards the substrate holder face, and hence towards the SAG mask 136, and the surface temperature ranges between the above-specified range, GaN nanowires progressively grow at the apertures 138 of the SAG mask 136. The evolution of the growth of an example GaN nanowire 140 is shown in FIG. 2B. As shown, each GaN nanowire 140 has a base 142 at a corresponding aperture 138, an elongated body 144 extending transversally to the substrate and a tip 146. In some embodiments, some of the tips 146 of the GaN nanowires 140 end in a flat top facet 148 parallel to the semiconductor substrate 106. In some embodiments, the tips 146 of the GaN nanowires 140 end in a uniform wurtzite-like structure 150, such as shown in the right-hand side inset of FIG. 2B.

It was found that when growth occurs under the above-mentioned growth conditions, the GaN nanowires 140 grow into a relatively uniform geometry, a substantially uniform length, a substantially uniform cross-sectional shape, a substantially uniform thickness, a substantially uniform tip shape, or a combination thereof. An example of which is shown in FIG. 2C. Accordingly, the semiconductor substrate 106 incorporating such a uniform array 152 of GaN nanowires 140 can be advantageously used in a number of applications including, but not limited to, photovoltaic devices, field effect transistors, light emitting diodes, lasers, photocatalysts, nanogenerators, to name a few examples. In some embodiments, each GaN nanowire 140 has a series of longitudinal sections having different doping along the length of the GaN nanowire. The sections can include a first section being n-doped, a second, intermediary section being i-doped and a third section being p-doped, depending on the embodiments.

Still referring to FIG. 2C, the semiconductor substrate 106 can be part of an optical emitting device 154 in some embodiments. For instance, in these embodiments, when the GaN nanowires 140 are electrically pumped using a current I greater than a current threshold Iₜₕᵣₑₛ, the optical emitting device 154 can generate a laser signal generally perpendicularly to the semiconductor substrate 106. In these embodiments, the optical emitting device 154 can be referred to as a vertical-cavity surface-emitting laser. Thanks to the bandgap of the GaN nanowires 140, the laser signal can include optical energy distributed within an ultraviolet range (e.g., 100-400 nm) of the electromagnetic spectrum, even when operated at room temperature. In some embodiments, the optical emitting device 154 is provided with an electrode, e.g., a graphene electrode 156, which sits atop the flat top facets 148 of the GaN nanowires 140.

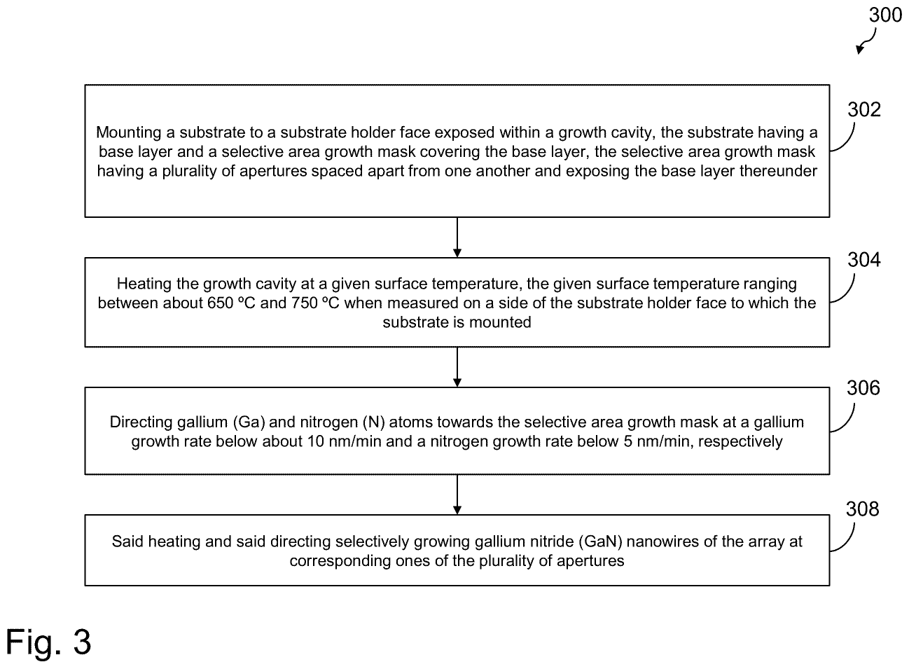

FIG. 3 shows a flow chart of an exemplary method 300 of manufacturing an array of gallium nitride (GaN) nanowires via selective area growth.

As shown, at step 302, a substrate is mounted to a substrate holder face exposed within a growth cavity. The substrate typically have a base layer and a SAG mask covering the base layer. The SAG mask has a number of apertures which are spaced apart from one another and which expose the base layer thereunder.

At step 304, the growth cavity is heated at a given surface temperature and maintained at that given surface temperature for a given period of time. The given surface temperature ranges between about 650° C. and 750° C. when measured on a side of the substrate holder face to which the substrate is mounted. In some embodiments, the given surface temperature preferably ranges between about 710° C. and 730° C., and most preferably is about 720° C.

At step 306, gallium (Ga) and nitrogen (N) atoms are directed towards the selective area growth mask at a gallium growth rate below about 10 nm/min and a nitrogen growth rate below 5 nm/min, respectively. Depending on the embodiment, the gallium growth rate can range between 1 and 10 nm/min, preferably between 2 and 8 nm/min and most preferably between 1.5 and 5 nm/min. In some embodiments, the nitrogen growth rate can range between 2 and 5 nm/min, preferably between 3 and 4 nm/min.

At step 308, the step 304 of heating and the step 306 of directing selectively grow the GaN nanowires of the array at corresponding ones of the apertures of the SAG mask. Each GaN nanowire has a base at a corresponding one of the apertures, an elongated body extending transversally to the substrate and a tip. In some embodiments, some of the tips of the GaN nanowires end in a planar top facet parallel to the substrate. Additionally or alternately, the tips can form a uniform wurtzite-like structure.

In some embodiments, the method 300 includes a step of growing, depositing or applying a graphene layer above the tips of the GaN nanowires. The graphene layer can partially or wholly cover the array of GaN nanowires. In these embodiments, the method 300 can include a step of electrically pumping the array of GaN nanowires at least partially via the graphene layer, and a step of generating a laser signal in response to said pumping. The electrical pump can include a step of applying a current across the array of GaN nanowires, the current exceeding a lasing current threshold. It was found that the array of GaN nanowires manufacturing using the method 300 can allow lower lasing current threshold. By doing so, the amount of energy required to achieve lasing operation is lower than using conventional array of GaN nanowires.

### Example 1—Low-Temperature Selective Area Epitaxy of GaN Nanowires: Towards a Top-surface Morphology Controllable Fully Epitaxial Nanophotonic Platform

Gallium nitride (GaN) nanowires by selective area epitaxy (SAE) is an emerging platform for nanophotonic devices. Nonetheless, the use of high substrate temperature in SAE limits the development of this technology. In this work, we report the SAE of GaN nanowires at low substrate temperatures by radio-frequency plasma-assisted molecular beam epitaxy. Excellent selectivity is obtained at low substrate temperatures; the area without patterning is nearly free of any growth. Furthermore, a delicate control on the nanowire top-surface morphology is enabled by the low temperature epitaxy, from irregular shape to hexagonal shape with semipolar top planes, to hexagonal shape with polar c-planes on top, with controlled polar c-plane size. Such a low temperature SAE of GaN nanowires, together with the elegant control on the nanowire top-surface morphology, will enable a fully controllably epitaxial nanophotonic platform, benefiting the development of a wide range of photonic devices such as light-emitting diodes, lasers, single photon sources, and multifunctional photonic devices.

Nanophotonics has been an attractive field to study, not only for the fundamental light science, but also for device applications related to light emitting, sensing, artificial photosynthesis, and quantum computing. Combining nanophotonic devices with the existing semiconductor device platforms through a simple epitaxial process will further extend their functionality. In this context, gallium nitride (GaN) nanowires have been investigated heavily in the past, due to the possibility of forming GaN nanowires on a wide range of substrates. Moreover, they are important “seeding” layers for the fabrication of scalable InGaN nanowire visible and AlGaN nanowire deep ultraviolet photonic devices at a wafer scale. Furthermore, GaN nanowires by selective area epitaxy (SAE) bring additional benefits and novel device developments, such as improving the light extraction efficiency of light emitting devices, novel photonic crystal lasers, and single photon sources, due to the control on the nanowire formation site and size.

Hitherto, metalorganic chemical vapour deposition (MOCVD) and radio-frequency (RF) plasma-assisted molecular beam epitaxy (PAMBE) are the two major approaches for photonic device development with SAE GaN nanowires. Nonetheless, there are two major issues. First, high substrate temperature is needed. The problem of using high substrate temperature is that high substrate temperature is unfavorable for p-type dopant (e.g., Mg, Be) incorporation into GaN, and it is well-known that low substrate temperature is preferred to incorporate Mg into III-nitrides. Therefore, high substrate temperature might limit the device development using SAE GaN nanowires. However, for MOCVD, it is always a higher temperature technique compared to MBE, even for thin film growth, whereas for MBE, to enable SAE, high substrate temperature is required. This is due to the highly reactive Ga on most surfaces and the need to increase Ga surface diffusion and desorption to obtain selectivity, i.e., nanowire formation only takes place in the desired nanoholes.

As such, given the lower growth temperature with MBE compared to MOCVD, SAE by MBE might be more desirable. It is worth noting that the very challenging green surface emitting lasers have been recently demonstrated using SAE GaN nanowires by MBE. Despite of the progress, less attention has been paid to the top-surface morphology control of SAE GaN nanowires by MBE. Such a control, however, is necessary. This is because the terminating surface of the nanowires will determine the growth of the next layers on top, e.g., InGaN quantum dots/disks, AlGaN nanowire segments, or the hetero-integration of other semiconductor nanowires, e.g., ZnO nanowires, and consequently affect their electrical and optical properties and thus the overall performance of final device structures.

In this example, we investigate the SAE of GaN nanowires at low substrate temperatures by MBE. It is found that the combination of low substrate temperature and low nitrogen flow rate can render an extraordinary selectivity of GaN nanowires. In specific, the area without patterning is nearly free of any growth—a significant improvement from the previous reports. Moreover, the use of low substrate temperature further enables a delicate control on the nanowire top-surface morphology as growth condition and pattern design change, due to the overall increased local III/V ratios compared to using high substrate temperatures. As such, this study paves the cornerstone for a fully controllable epitaxial nanophotonic platform, benefiting a wide range of photonic device development including multifunctional photonic devices.

In this study, the manufacturing process involves the use of a growth chamber. More specifically, SAE of GaN nanowires was performed on Ti-patterned GaN-on-sapphire template. A thin Ti layer (˜10 nm) was employed as the growth mask, and periodical nanoholes with diameter d and center to center spacing a arranged in a square lattice were patterned using e-beam lithography (EBL) and reactive ion etching (RIE). It is also noted that the nanohole diameter refers to the size after the patterning process. Prior to the growth of GaN nanowires, such Ti-patterned wafers were nitridized at 400° C. in the growth chamber to prevent crack and degradation at elevated temperatures during the growth.

The GaN nanowires in this study were grown with a substrate temperature (T_{sub}) in the range of around 800° C. to 880° C. Here, T_{sub} refers to the thermocouple reading. Ga desorption test was performed in order to understand the surface temperature of non-patterned GaN-on-sapphire template. At a temperature of 900° C., the Ga desorption time was tens of seconds. As such, although the presence of Ti or TiNₓ may affect the surface temperature, T_{sub} used in this study correlated to significantly lower surface temperatures, compared to the surface temperatures in the previous studies. The Ga flux in this study was fixed at around 2.5×10⁻⁷ Torr, whereas the nominal N flux was estimated to be around 1×10⁻⁷ Torr for a nitrogen flow rate of 0.3 sccm. In the rest of the paper, we use nitrogen flow rate to denote N flux (N_{flux}). The detailed growth conditions for GaN nanowires will be described together with the results. The growth duration for all samples was 2 hours.

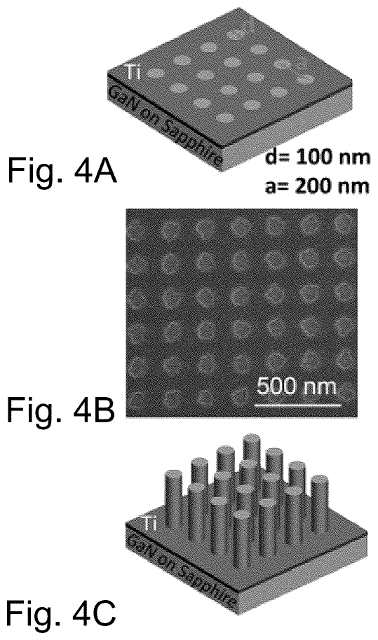

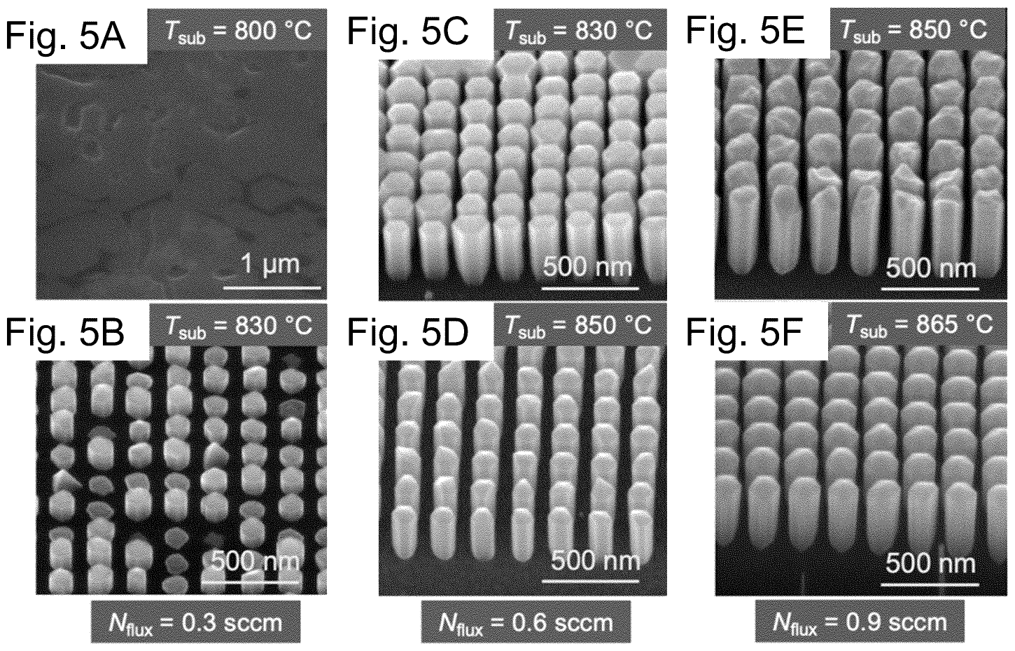

We first investigate the effect of growth conditions including T_{sub} and N_{flux} on the selectivity and morphology of the SAE GaN nanowires. In this regard, d is fixed at 100 nm and a is fixed at 200 nm. This is schematically shown in FIG. 4A. FIG. 4B shows the SEM image of such a pattern prior to the MBE growth. FIG. 4C shows the schematic of the SAE GaN nanowires. SEM images for samples under different growth conditions are shown in FIG. 5. FIG. 5A shows the SEM image for the sample grown at T_{sub}=800° C. and N_{flux}=0.3 sccm. As can be seen, only film-like GaN is grown. Further increasing T_{sub} to 830° C. while keeping N_{flux} to be the same, nanowires are formed. However, the nanowires are nonuniform: as can be seen in FIG. 5B, the height and diameter of nanowires are varying significantly. There is also a variation of the nanowire shape, e.g., irregular shape, hexagonal shape. Moreover, for some nanoholes, GaN just fills the nanoholes and nearly no vertical growth takes place (i.e., no GaN nanowire growth). Improvement on the nanowire height uniformity is obtained by increasing N_{flux} to 0.6 sccm with T_{sub} remained to be the same (FIG. 5C). Further increasing T_{sub} to 850° C. with N_{flux} kept being the same leads to the formation of hexagonal shaped nanowires with semipolar planes (FIG. 5D). However, keeping T_{sub} at 850° C. and increasing N_{flux} to 0.9 sccm degrades the nanowire morphology, i.e., the top-surface shape becomes irregular (FIG. 5E). The hexagonal shaped nanowires with semipolar top planes are restored with further increasing T_{sub} to 865° C. with N_{flux} remained at 0.9 sccm (FIG. 5F), and the overall nanowire uniformity is also improved compared to FIG. 5D.

The systematic change of the nanowire top-surface morphology with changing growth conditions can be explained by the interplay between the impinged Ga and N species. Different from Ga that diffuses along a surface, N impinges locally. As such, due to a shadow effect, the nonuniform incorporation of N can lead to irregular top surface. In the meantime, local N-rich regions could also mean Ga deficiency and a higher Ga diffusion barrier, which in consequence leads to a rough surface. On the other hand, increasing T_{sub} enhances Ga diffusion and thus leads to an improved top-surface morphology. As such, sufficient Ga diffusion and uniform N incorporation are necessary factors to maintain uniform hexagonal shaped nanowires (with semipolar top planes).

Excellent selectivity is obtained in this study, i.e., the nanowires only form in the nanoholes, and there does not exist any growth in the area without patterning. This can be seen from FIGS. 5D and 5F. This is in contrast to conventional SAE of GaN nanowires at high T_{sub}, wherein although the selectivity can be obtained in the patterned area, the area without patterning, even the area adjacent to nanowire arrays but outside the nanowire arrays, is often accompanied by the formation of unwanted GaN thin film or micro/nanocrystals with irregular shapes. This can be explained by that, due to the use of low T_{sub}, high N_{flux} is not needed anymore, as such, the probability of formatting GaN on the mask is also reduced.

In this example, we have also investigated the growth at higher T_{sub} with N_{flux}=0.9 sccm, and no GaN growth took place. It is known that the growth can be restored by using high N_{flux}; however, as the present study focuses on the low-temperature SAE of GaN nanowires, we did not further increase N_{flux} beyond 0.9 sccm.

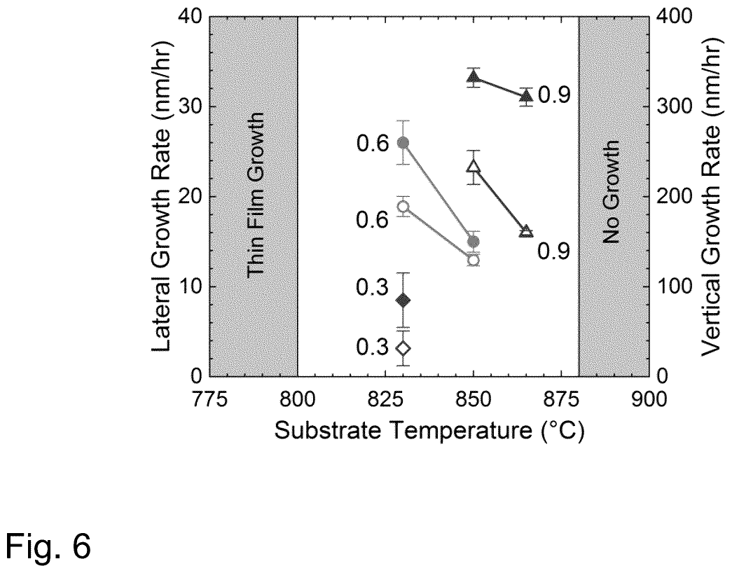

FIG. 6 shows the estimated growth rates as a function of T_{sub} and N_{flux}, together with the two regimes of thin film growth and no growth. Here, the lateral growth rate was calculated from the difference between the nanowire diameter and the nanohole diameter d, and the vertical growth rate was calculated from the nanowire height. The values shown in the figure are statistical averages, and the error bars are standard deviations. It is seen that, by increasing N_{flux}, both lateral and vertical growth rates increase (at a given T_{sub}), whereas both the lateral and vertical growth rates decrease as T_{sub} increases (at a given N_{flux}). The increasing in both vertical and lateral growth rates as the increase of N_{flux} has been observed commonly—the increase of N_{flux} increases the probability for the GaN formation. On the other hand, the reduction of both the lateral and vertical growth rates as the increase of T_{sub} can be attributed to the enhanced Ga desorption as T_{sub} increases.

It is further noted that, although low N_{flux} values are used in the present study, relatively high lateral growth rates can be obtained. This contrasts with the previous studies at high T_{sub}, wherein to obtain relatively high growth rates high N_{flux} values are needed. This is due to the use of low T_{sub} in the present study, such that the Ga adatom vertical diffusion is suppressed. This also explains the formation of GaN thin film in FIG. 5A. It is further noted that, due to the lateral growth (i.e., the nanowires outgrow the nanoholes), the shape of the nanowire sidewall is independent of the nanohole shapes (note that in FIG. 4B the nanoholes have irregular shapes). It is also noted that, the fact that the growth rates increase as N_{flux} increases is an indication of N-limited growth.

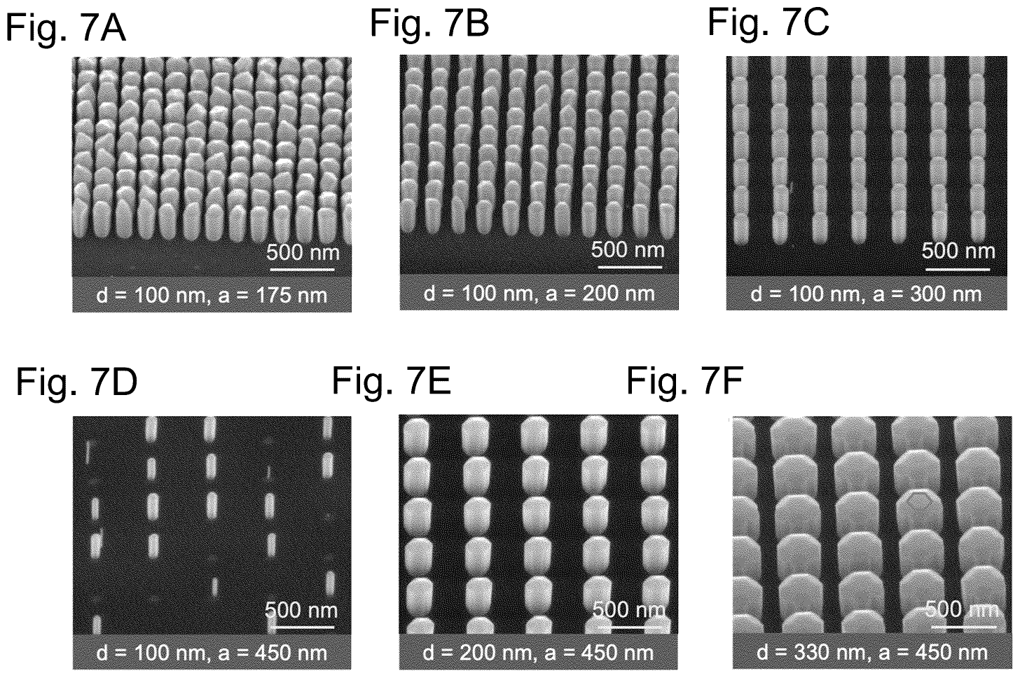

We next investigate the design pattern dependent growth at T_{sub}=850° C. and N_{flux}=0.6 sccm. In this regard, d was first kept at 100 nm, whereas a was increased from 175 nm to 450 nm; and then, a was kept at 450 nm with d increasing from 100 nm to 330 nm. SEM images of GaN nanowires on these patterns are shown in FIG. 7. For all the patterns, excellent selectivity is achieved and there does not exist any growth in the area without patterning. It also can be seen that, by increasing a from 175 nm to 450 nm (FIGS. 7a to 7d), the nanowire morphology is improved significantly, i.e., from irregular top surface to relatively uniform semipolar top surface. This can be explained by the reduced shadow effect related to the N incorporation, i.e., N is incorporated more uniformly; and for such a design pattern dependent morphology variation, it is mainly limited by the N incorporation.

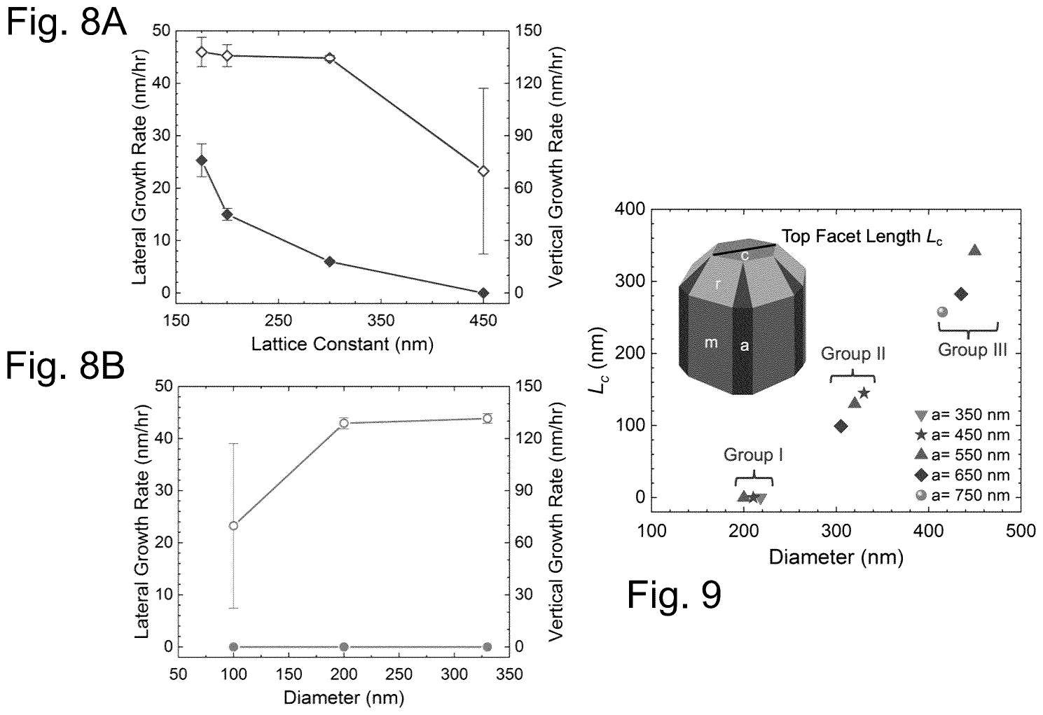

In the meantime, both nanowire diameter and height reduce as a increases. In the extreme case for a=450 nm, the nanowires are significantly shorter and thinner. In fact, many nanoholes (or equivalently, apertures) are without nanowires, suggesting that the nucleation in the nanoholes seems to be suppressed at large a. This trend is more clearly shown in FIG. 8a: for d=100 nm, when a is less than 450 nm, the vertical growth rate is nearly constant, but it drops drastically for a=450 nm. The lateral growth rate is also dropped as a increases. Similar behavior has been observed previously for both small nanoholes (size less than 50 nm) and spacing of 70 nm as well as large nanoholes (100 nm) and spacing of 600 nm, due to a random nucleation issue, i.e., with certain nanohole size and spacing combinations, the nanowire growth does not take place in the nanoholes; such an issue can be potentially solved by shutter modulated growth.

Spacing dependent growth rates have been used to estimate the Ga diffusion length L_{Ga}. In general, it is found that as the nanohole spacing increases, the diameter and height of the nanowires increase followed by a saturation trend, when the spacing is two folds of L_{Ga} or longer. In our case, nearly constant nanowire height is observed (except for a=450 nm, which has been explained), suggesting that in our case, the minimum spacing in the present study is significantly larger than L_{Ga}, i.e., L_{Ga} should be less than one half of 175 nm, consistent with the use of low T_{sub}. It should also be noted that the effect of T_{sub} is much stronger than N_{flux} on L_{Ga}. This short L_{Ga} also precludes us from entering (using patterns in this study) the Ga-limited growth regime with the formation of nanotubes.

Further keeping a=450 nm and increasing d from 100 nm to 330 nm (FIGS. 7d to 7f), the nanowire growth restores. This is more clearly shown in FIG. 8b. Large d (d>100 nm) leads to nanowires with similar height (vertical growth rate is around 130 nm/hr). On the other hand, it is noted that in these cases, there is nearly no lateral growth, i.e., the nanowires do not overgrow the nanoholes. As such, the shape of nanoholes affects the morphology of the nanowire sidewall (e.g., see FIG. 7f). The diameter dependent growth has been investigated in the past with fixed spacing, and the growth is at high T_{sub}. It is found that, nanowires can be formed for small nanoholes, whereas for large nanoholes, only pyramid shaped nanocrystals are obtained (i.e., the growth is locked to r-plane). This is attributed to the low local III/V ratio. In our case, due to the use of low T_{sub}, we are able to maintain a sufficient III/V ratio for the growth of nanowires. In some embodiments, the lattice constant can vary from 100 nm to 1000 nm. The aperture diameter can vary from 50 nm to 500 nm.

An interesting feature noted, though, is that as d increases, the nanowires begin to show a c-plane top facet. In specific, the nanowires grown with d of 200 nm show a hexagonal shape without c-plane, and with further increasing d to 330 nm, flat c-plane occurs on top, as schematically shown in FIG. 7f. The top facet length L_{c} (a measure of the c-plane size) as a function of d under different a is shown in FIG. 9. As can be seen, L_{c} increases as d increases, whereas L_{c} decreases as a increases (see Groups II and III). As with these design patterns, there is nearly no lateral growth, this plot simply reflects the correlation of L_{c} to the nanowire diameter, i.e., the larger the nanowire diameter is, the larger L_{c} is. This means that, in our growth window, L_{c} can be controlled either by d or a. Such an L_{c} variation with a and dis a reflection of the local III/V ratio variation due to the design pattern change, which in consequence changes the growth kinetics and surface energy minimization processes.

Lastly, it is worth mentioning that, in the present GaN nanowires the yellow photoluminescence band is negligible, suggesting that despite of using low T_{sub} for the SAE growth of GaN nanowires, high optical quality GaN nanowires can still be obtained.

In summary, we have demonstrated the selective area growth of GaN nanowires with relatively low substrate temperatures. The effects of growth parameters including the substrate temperature, metal fluxes, and nitrogen flow rates on both the selectivity and morphology of the nanowires are investigated. The dependency of the selectivity and morphology of the nanowires on the pattern design is also evaluated. Overall, the use of low substrate temperature enables several new findings: 1) Excellent selectivity. The area without patterning is nearly free of any growth, despite the short Ga diffusion length (tens of nanometers) at low substrate temperatures. This can be explained by, due to the use of low substrate temperature, only low nitrogen flow rates are needed for the nanowire growth, which in consequence reduces the probability of GaN formation on the mask. 2) Relatively high lateral growth rates can be obtained at low nitrogen flow rates. This is due to the suppression of Ga vertical diffusion at low substrate temperature. 3) A delicate control on the nanowire top-surface morphology. The use of overall low substrate temperature enhances local III/V ratios, which, together with the changes of substrate temperature, nitrogen flow rate, and pattern design, enriches the nanowire growth, enabling a controllable lateral growth rate and top-surface morphology, from irregular shape to hexagonal shape with semipolar top planes, to hexagonal shape with polar c-planes on top, with controlled polar c-plane size. Such a control represents a critical step towards a fully controllable epitaxial nanophotonic platform for a wide range of photonic devices.

### Example 2—Ultralow Threshold Surface Emitting Ultraviolet Lasers with Semiconductor Nanowires

Surface-emitting semiconductor lasers have changed our everyday life in various ways such as communication and sensing. Expanding the operation wavelength of surface-emitting semiconductor lasers to shorter ultraviolet (UV) wavelength range further broadens the applications to disinfection, medical diagnostics, phototherapy, and so on. Nonetheless, the UV surface-emitting lasers demonstrated so far are all using conventional vertical cavities, all with large lasing thresholds in the range of several hundred kW/cm² to MW/cm². In this example, we report ultralow threshold surface-emitting lasing in the UV range using novel epitaxial nanowire photonic crystal structures. Lasing at 367 nm is measured, with a threshold of only 7 kW/cm², a factor of 100× reduction compared to the previously reported surface-emitting UV lasers at similar wavelengths. Further given the excellent electrical doping that has already been demonstrated in nanowires, this work offers a viable path for the development of the long-sought-after surface-emitting semiconductor UV lasers.

Surface-emitting (SE) semiconductor lasers are important for a variety of fields such as photonics, information and communication technologies, and biomedical sciences. Compared to edge-emitting lasers, SE lasers offer a number of advantages such as low beam divergence, circular far-field pattern, fast modulation speed, two-dimensional integration capability, and so on. Over decades of development, gallium arsenide (GaAs)-based near-infrared (IR) SE lasers have turned into a billion-dollar industry, impacting both data communication and 3D sensing such as face recognition and time-of-flight imaging. The success of SE lasers in the near-IR unfortunately is not seen in the shorter visible and ultraviolet (UV) spectral ranges. For example, despite of the encouraging progress in gallium nitride (GaN)-based blue and green SE lasers in recent years, they have not yet reached the same level of maturity as that of their counterparts in the near-IR. In the UV range, the situation is even more lagging behind. The SE lasing demonstrated so far is all through optical pumping based on aluminum gallium nitride (AlGaN) alloys using conventional vertical cavities. Such structures are all with large lasing threshold power densities. For instance, the threshold power density for sub-280 nm SE lasing is 1.2 MW/cm², and even for SE lasing at longer wavelength (close to 400 nm) the threshold power density is in the range of around 200-400 kW/cm². Breakthrough in the SE UV laser development is pivotal to a variety of applications related to our daily life including disinfection, medical diagnostics, phototherapy, curing, and high-resolution 3D printing.

The primary challenges for the development of SE UV lasers based on AlGaN alloys using conventional vertical cavities lie in the difficulty in obtaining high-quality distributed Bragg reflector (DBR) mirrors (primarily limited by material quality due to large lattice mismatches), the difficulty in obtaining low resistivity AlGaN due to poor electrical doping (primarily p-type), and the complexity in the device fabrication process. Here, we demonstrate ultralow threshold SE lasing in the UV range using novel epitaxial nanowire photonic crystal (NPC) structures. The bottom-up nanowires have been proved to be able to improve the material quality due to the efficient strain relaxation to the large surface area. Furthermore, the electrical doping into nanowire is also proved to be better compared to planar counterparts, facilitating electrical injection. Moreover, the exploiting of the band-edge effect of photonic crystals for lasing can avoid the problematic DBR mirrors for the cavity formation. The SE UV lasing shown in this study is at 367 nm with a threshold of merely 7 kW/cm², a 100× reduction compared to the prior art at a similar lasing wavelength. The use of photonic crystal based SE lasers can also potentially offer uniform single mode over a large area and other benefits such as on-demand beam. The fully epitaxial NPC SE lasers can further enable the integration to other existing semiconductor device platforms for increased functionalities.

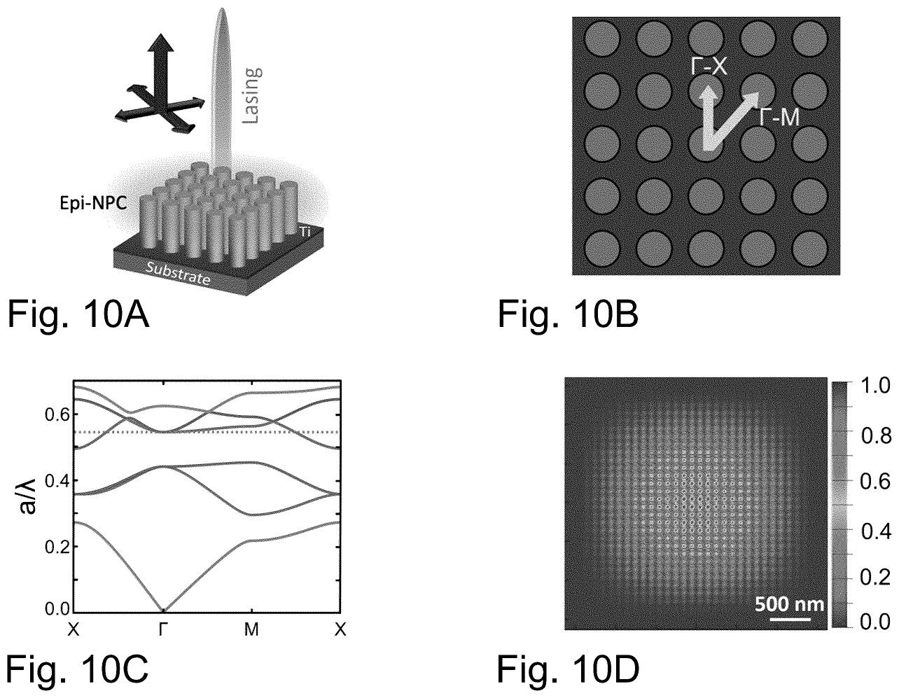

A schematic illustration of the device concept is shown in FIG. 10a, which utilizes NPC in a square lattice for the optical cavity formation to achieve SE lasing. The use of square lattice is favorable for single mode lasing as well as realizing various functionalities. An illustration of in-plane light beam propagation and diffraction to the normal direction forming SE lasing is also shown in the inset of FIG. 10a. FIG. 10b shows the top view of such NPC, with two specific directions Γ-X and Γ-M labeled. In this study, GaN nanowires were used and the light emission wavelength was at ˜364 nm, with a full-width half-maximum (FWHM) of 15 nm. Therefore, we design an NPC structure that can form a cavity to support the lasing emission around this wavelength. FIG. 10c shows the 2-dimensional (2D) transverse-magnetic (TM) photonic band structure using 2D space and wave optics package in COMSOL Multiphysics, with a lattice constant (a, center to center distance) of 200 nm and a nanowire diameter (d_{NW}) of 173 nm. The dashed line represents the reduced frequency (a/λ). In general, at photonic band edges, the light group velocity becomes zero, i.e., dω/dk→0, so that standing waves can be formed, and lasing can be achieved using such slow light, due to a significantly enhanced interaction time between the radiation field and gain medium. From FIG. 10c, it is seen that the reduced frequency aligns with band edges at a/λ˜0.545 (Γ point), suggesting the formation of a standing wave and a possible lasing (if gain is greater than loss) at this point. Furthermore, at Γ point, the light beam can also be diffracted normal to the photonic crystal plane, forming SE lasing. Moreover, 2D coupling could be possibly formed, due to the band crossing at this point. FIG. 10d shows the mode profile (|E|2) of the designed NPC structure simulated using three-dimensional (3D) finite difference time-domain (FDTD) method, manifesting the formation of an in-plane photonic crystal cavity.

Experimentally, the NPC structure is formed on a patterned GaN-on-sapphire substrate using molecular beam epitaxy (MBE). To form the pattern, 10 nm Ti was first deposited using an electron beam evaporator, which was followed by electron beam lithography (EBL) and reactive ion etching (RIE) to create nanoholes with diameter (d) and lattice constant (a) arranged in a square lattice. To form the NPC, it followed a two-step process. Ti-patterned substrate was first nitrided at 400° C. in the MBE growth chamber, to prevent crack and degradation at elevated temperatures. This was followed by the growth of GaN nanowires. The growth condition included a substrate temperature (T_{sub}) of 865° C., a nitrogen flow rate of 0.9 sccm, and a Ga flux of 2.5×10⁻⁷ Torr.

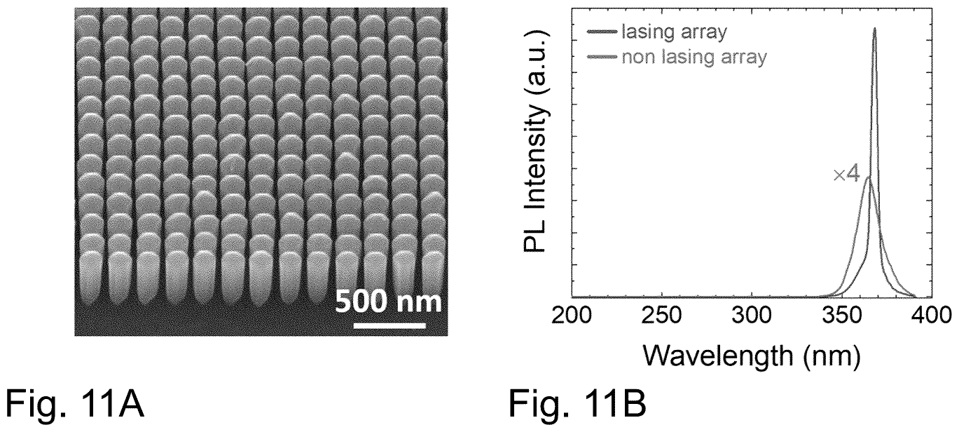

A scanning electron microscope (SEM) image of the NPC on a patterned substrate with a lattice constant (a) of 200 nm is shown in FIG. 11a. The SEM image was taken at a tilting angle of 45° using a field-emission (FE) SEM system. It is seen that the nanowires are highly uniform. Using a statistical measurement based on the SEM image, the average d_{NW} was 173.2 nm, with a standard deviation of 4.4 nm. These parameters correlate very well to the design parameters in FIG. 10c. In this study, in order to achieve a nanowire array that is close to the design, extensive MBE growth runs were carried out by carefully tuning the lateral growth rate with varying growth conditions and the pattern design (mainly the d value). We have previously established the correlation of the lateral growth rate with the growth condition and pattern design. Also noted is the ultra-clean area surrounding the nanowire array, which is due to the use of low-temperature selective area epitaxy (LT-SAE).

FIG. 11b shows the room-temperature (RT) photoluminescence (PL) spectrum collected from the top surface of the NPC structure (denoted as “lasing array”), excited by a 213 nm pulse laser under a power density of 63.5 kW/cm². The laser light was focused on the sample surface through a focus lens (the beam spot size was estimated to be around 9×10⁻⁴ cm²), and the emitted light was also collected from the sample surface using a focus lens, which was further coupled to an optical fiber and an UV spectrometer. Also shown in FIG. 11b is the PL spectrum of an array of a=600 nm and d_{NW}=300 nm (which does not correlate to any band edge modes and denoted as “non-lasing array”) measured under the same condition. It is seen that a strong PL emission is measured from the lasing array with a narrow linewidth, whereas the PL emission from the non-lasing array is much weaker (roughly a factor of 10× lower) with the linewidth remaining broad.

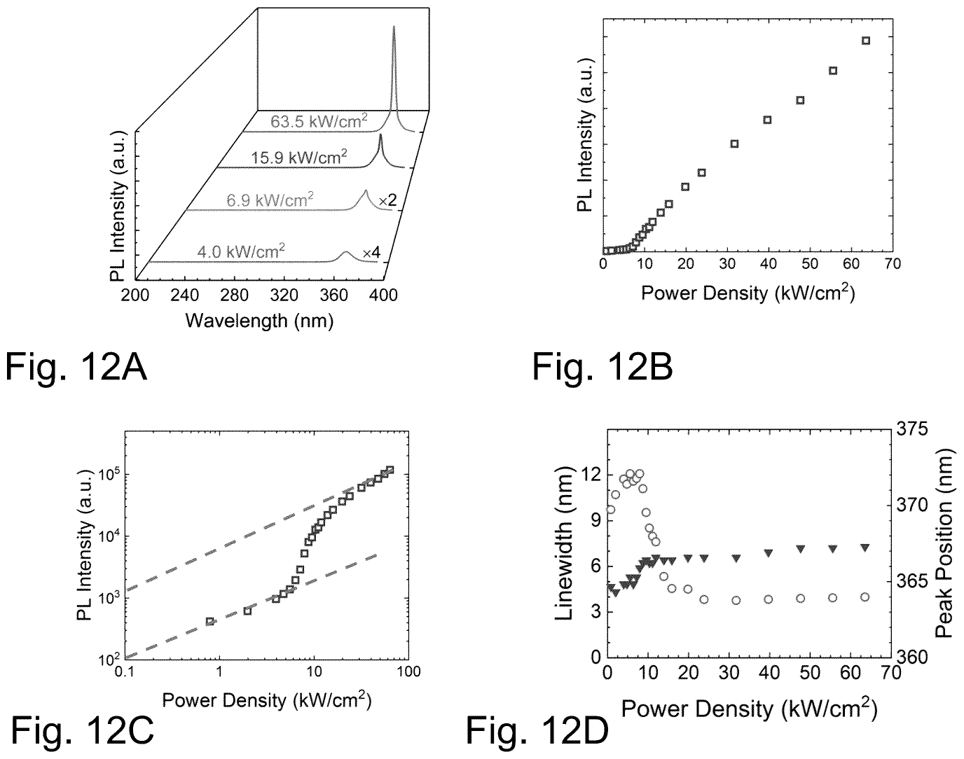

Detailed measurements further confirm the achievement of a ultralow threshold SE lasing. Shown in FIG. 12a are the light emission spectra under different excitation densities. It is seen that as the excitation density increases, the spectra become narrow, accompanied by a rapid increase of the PL intensity. This trend is more clearly shown by the L-L (light-out versus light-in) curve in FIG. 12b, indicating a clear threshold around 7 kW/cm². The lasing is further confirmed by examining the L-L curve in a logarithmic scale. As shown in FIG. 12c, a clear S-shape, corresponding to the spontaneous emission (linear), the amplified spontaneous emission (super linear), and the lasing (linear), is observed, being the confirmative evidence for lasing.

It is also noted that, in this example, the lasing light intensity collected from the side is only ˜ 1/30 compared to that collected from the top, suggesting the surface dominated light emission. In this study, we have also measured the PL spectra of GaN-on-sapphire template and GaN-on-sapphire with Ti mask, confirming that the lasing is due to the light emission from the NPC. It is also worth noting that, as the lasing array and non-lasing array have the same height, it rules out that the lasing is due to the formation of a Fabry-Perot (FP) cavity.

The spontaneous emission coupling factor β was further estimated by using the intensity ratio of the spontaneous emission versus the lasing emission, as indicated by the dashed lines in FIG. 12c. A β factor of around 0.08 can be derived. This β factor is comparable to the previously reported photonic crystal SE lasers and is larger compared to the values reported in conventional vertical cavity SE UV lasers, due to the efficient photon coupling in a photonic crystal cavity.

FIG. 12d shows the nearly stable lasing emission wavelength and the linewidth reduction around the lasing threshold. In general, lasing in the UV range has a spectral linewidth of around 1-2 nm. The linewidth obtained in the present study, however, is broader, suggesting a mediocre optical cavity. This might not be entirely surprising. From the band structure shown in FIG. 10c, a strong 2D in-plane coupling is not likely, limiting the quality of the optical cavity. Moreover, the optical leakage to the GaN template due to the smaller refractive index of the GaN-air composite could also limit the quality of the optical cavity. Nonetheless, even with such a mediocre optical cavity, ultralow lasing threshold is obtained, suggesting a great potential of further decreasing the lasing threshold.

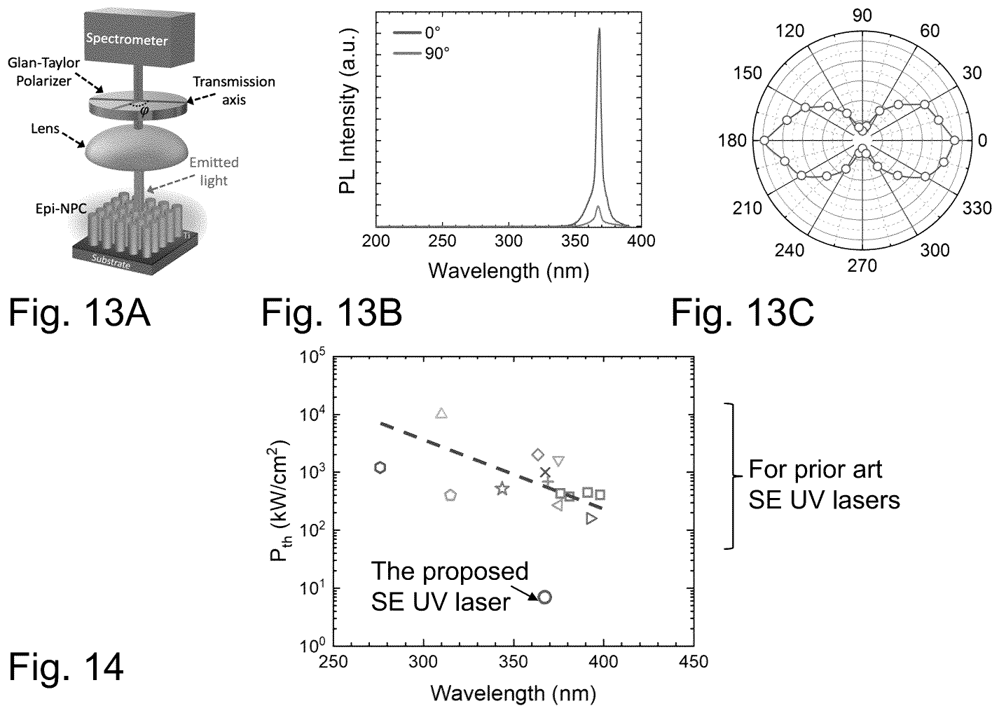

The in-plane polarization at Γ point is investigated in the end. In this regard, the light emission was collected from the device top with a polarizer inserted in the light collection path. This is schematically shown in FIG. 13a: a Glan-Taylor polarizer is placed in the light collection path, and the in-plane angle φ is also labeled. Here, φ=0° means the electric field is along the transmission axis of the polarizer. From FIG. 13b, it is seen that the light intensity at φ=0° is roughly about 10 times stronger compared to the light intensity at φ=90°, suggesting the emitted light is highly polarized in-plane at Γ point. FIG. 13c further shows the light intensity at various angle φ. If defining the polarization ratio (degree of polarization) as ρ=(Iₘₐₓ−Iₘᵢₙ)/(Iₘₐₓ+Iₘᵢₙ), a value of around 0.8 is obtained, suggesting a high degree of in-plane polarization. Similar polarization ratio has been reported in the past for InGaN based photonic crystal SE lasers.

Such an in-plane polarization could be attributed to the breaking of ideal symmetric feedback of the 2D photonic crystal lattice, i.e., in-plane light beams propagating in different directions could not be equally diffracted by the 2D lattice and light beams diffracted in certain directions thus could have higher intensities, becoming “in-plane polarized”; and this breaking of symmetric feedback could be due to factors such as certain degree of small disorders in the lattice and the finite size of the lattice.

FIG. 14 shows the comparison plot of the lasing threshold in the present study versus the lasing thresholds reported in the past for SE UV/near-UV lasers at different wavelengths. It is seen that, prior to this study, the lasing threshold is in the range of several hundred kW/cm² to MW/cm², and the lasing threshold increases as the lasing wavelength becomes shorter, as indicated by the dash line. For lasing at a wavelength similar to the wavelength in the present study, the threshold is around 0.7-1 MW/cm². In contrast, the lasing threshold in the present study is only 7 kW/cm². Accordingly, it is intended that a optical emitting device incorporating the array of uniform GaN nanowire can have a better resonator quality or Q-factor. As such, the lasing threshold power density threshold of the proposed optical emitting device can be significantly lower than with existing UV lasers. As shown in FIG. 14, the optical emitting device can have a lasing threshold power density threshold below 100 kW/cm², and most preferably below 10 kW/cm².

In summary, in this example we have demonstrated ultralow threshold SE UV lasing using novel epitaxial semiconductor nanowire based photonic crystal structures. The measured lasing wavelength is at 367 nm, with a lasing threshold of merely 7 kW/cm², two orders of magnitude lower compared to the previously reported SE UV lasers at similar lasing wavelengths. This lasing threshold is also more than one order of magnitude lower compared to the previously reported SE near-UV lasing. A possible reduction of lasing threshold can be obtained by further introducing strong 2D coupling in the photonic crystal cavity as well as reducing the optical leakage in the vertical direction. Further given the excellent electrical doping that has already been demonstrated in nanowires and the fully epitaxial process, this study provides a viable path for the development of electrically injected SE semiconductor lasers in the UV range, with controlled beam properties and integration capability to other existing semiconductor device platforms for increased functionalities.

### Example 3—Low Threshold DBR-Free UV VCSELs with GaN Nanowires by Selective Area Epitaxy

This example demonstrates a new architecture for vertical cavity surface emitting lasers (VCSELs) in the ultraviolet (UV) range, using nanowire arrays synthesized at low substrate temperatures. Lasing at 364 nm is measured, with a threshold of 20 kW/cm², at least a factor of 20× reduction compared to the prior art.

In the past, UV VCSELs are appealing light sources for atomic clock. They can also be potentially used as devices for surface disinfection and optical communication (e.g., non-line of sight, NLOS). Compared to edge emitting devices, surface emitting devices are easier for integration. Limited by bandgap energies, there are not many semiconductor candidates that can be used for UV VCSEL development—gallium nitride (GaN) is the most attractive one so far. Nonetheless, the progress of GaN based UV VCSEL is very slow. One major reason is the difficulty to get high-quality distributed Bragg reflector (DBR) mirrors. As such, there are only limited demonstrations of GaN based UV VCSELs, and threshold is typically on the order MW/cm², with best in the range of 400 kW/cm².

We show a new architecture for UV VCSEL, which exploits bottom-up GaN nanowire arrays by selective area epitaxy. The cavity is formed by utilizing the slow light mode at the photonic band edge. The dash line (reduced frequency) aligns with a band edge mode that supports surface emitting at 364 nm.

In such embodiments, as the excitation intensity increases, a lasing peak at 364 nm can appear. The linewidth is around 2 nm, limited by the spectral resolution of the detector. No shift of the lasing peak is seen. A clear s-shape, which corresponds to spontaneous emission, amplified spontaneous emission, and lasing, is clearly seen, confirming the lasing action. It can also be seen that the threshold is only around 20 kW/cm².

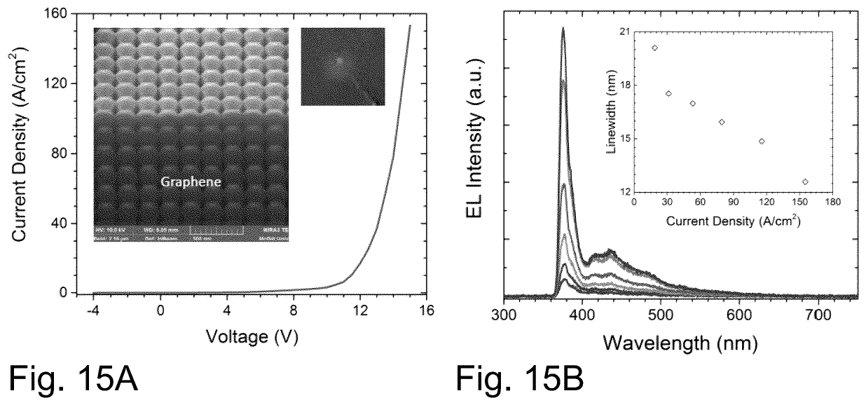

As discussed in introduction, conventional DBR is not a favorable technology for UV VCSEL. Using properties of photonic crystals (PCs) is appealing. So far, there are two ways of obtaining PCs: top-down etching and bottom-up nanowire arrays, and the latter is an emerging field. Regardless of approach (bottom-up or top-down for PCs), no demonstration of UV VCSELs using PCs prior to this ROI. A few reasons could be: 1) top-down etching induces defects that are detrimental to UV VCSELs; 2) bottom-up process is emerging; and 3) bottom-up process requires selective area epitaxy and such an epitaxy process requires delicate control on growth parameters. In this example, we explored for the first time low-temperature selective area epitaxy and demonstrated an elegant control on the epitaxial nanowire growth. This led to the breakthrough on UV VCSELs. FIGS. 15A and 15B show exemplary results obtained using the UV VCSELs manufactured using method proposed herein. As can be appreciated, lasing activity can be achieved using an electrical pumping technique requiring relatively low current densities. As best shown in FIG. 15A, the array of GaN nanowires has a brighter region which is exempt of graphene and a darker region which is covered with a graphene layer. It was found convenient to use such a UV VCSELs as the graphene layer/electrode has a satisfactory transmission across the UV range of the electromagnetic spectrum. Moreover, it was found that the electrical pumping of such UV VCSELs can be more energy efficient than optical pumping of competitive technologies. The inset shows a top view of an example of a graphene electrode, with the light spot representing a point of contact on the graphene electrode.

UV VCSELs are important in a number of fields such as atomic clock, disinfection, and optical communication. UV VCSELs with conventional DBR only have high lasing thresholds. Using band edge modes of PCs is appealing but top-down etching induced defects are detrimental for laser devices. Using bottom-up PCs is an emerging field, and the control on the material is more demanding. We have recently gained this capacity and led to the breakthrough of UV VCSEL.

It is noted that the above examples could have equivalently performed using any type of group III-nitride nanowires in some other embodiments. For example, the next example involves AlGaN, GaN, or InGaN nanowires.

### Example 4—Architecture for Surface Emitting Lasers with on Demand Lasing Wavelength

Surface emitting (SE) lasers are indispensable in everyday life, with applications in a wide range of fields from optical communications and data transmission to medical diagnostics and therapeutics. In comparison to their edge emitting counterparts, SE lasers promise high beam quality, high output power of a single mode, and fiber optics integration, amongst other benefits. Despite of the exciting progress in the field, there are limited choices of lasing wavelengths even today. From the application viewpoint, it is desirable to have an architecture that can allow SE lasing in a wide spectral range based on need/demand, which, in the meantime, could also open new applications. Moreover, regardless of the lasing wavelength, the dominant architecture for SE lasers today is constructed from a vertical cavity sandwiched between distributed Bragg reflectors (DBR), also known as “vertical cavity surface emitting lasers” or “VCSELs”, which require complex epitaxy and fabrication processes, and having VCSELs in the ultraviolet (UV) range remains to be a challenge.

On the other hand, semiconductor nanostructures have been a fascinating platform for light emitting devices. Back to two decades ago, lasing from single semiconductor nanowires have been demonstrated. Among various semiconductor nanowire systems, III-nitride nanowires are an appealing material platform for the development of light emitting devices due to a number of advantages, such as chemical stability, mechanical strength, and the direct, ultrawide, and tunable bandgap energies ranging from the near-infrared (NIR) to UV. The bottom-up III-nitride nanowires have been proved to be able to improve the material quality compared to planar counterparts, due to the efficient strain relaxation to the large surface area. Furthermore, the electrical doping into nanowire is also proved to be better compared to planar counterparts, facilitating electrical injection. Moreover, through the use of nanowire photonic crystals (NPC), it is possible to not only manipulate light with unrivaled precision, but also eliminate the need of problematic DBR mirrors for the optical cavity formation in conventional VCSELs, by exploiting approaches such as photonic crystal band edge modes. Indeed, recent years have witnessed the rising of large-scale light emitting devices using III-nitride nanowires, including ultrasmall, color tunable light-emitting diodes (LEDs), green color SE lasers, and ultralow threshold SE UV lasing under optical pumping, to name just a few.

In this example, a path for SE lasers with lasing wavelength on demand is demonstrated by exploiting epitaxial III-nitride nanowire photonic crystals (epi-NPC). III-nitrides have an ultrawide bandgap energies ranging from NIR to UV, meaning a wide range of gain can be supported. Further engineering the band edge mode at Γ point of photonic crystals for optical cavity formation, SE lasing at desired wavelengths can be obtained. Toward this, it is first demonstrates that through the control of the substrate patterning process, nanowire epitaxy masks with desired patterns can be obtained. This, together with the precisely controlled growth conditions, nanowires with desired arrangements can also be obtained. Further by controlling the material composition, e.g., whether aluminum gallium nitride (AlGaN) or indium gallium nitride (InGaN) is synthesized, the optical bandgap widely varying from sub-250 nm to 500 nm is obtained, with a potential expansion down to 200 nm and up to 2 μm. Subsequently, this example proceeds to demonstrate optically pumped SE lasing using low In content (including GaN) InGaN-based epi-NPC, and lasing at various UV-A wavelengths is achieved with ultralow threshold (10 KW/cm² or less), which is a remarkable reduction compared to conventional VCSELs at similar wavelengths. In the end, utilizing graphene as electrode, electrically injected devices are fabricated, which exhibit amplified spontaneous surface emission in the UV range. This is also the first achievement of electrically injected, amplified surface emission in the UV range.

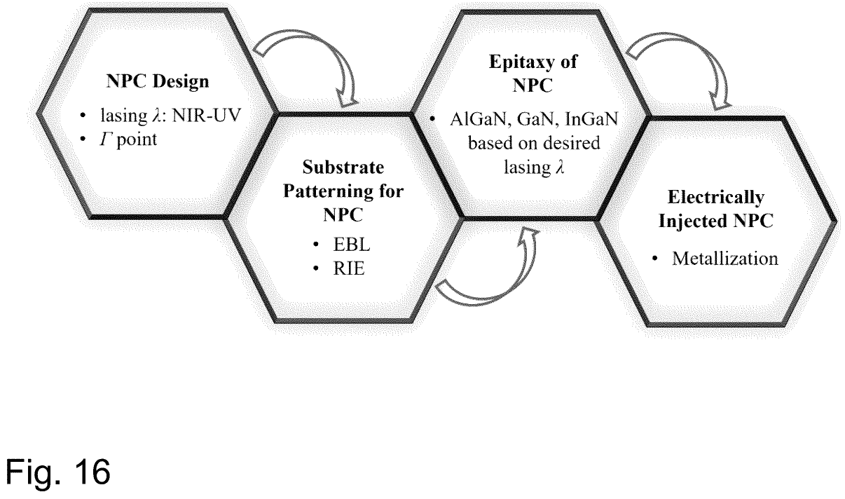

The generic conceptual framework is shown in FIG. 16. First, numerical simulations on photonic band structure and electric field distribution are conducted, in order to obtain the photonic crystal structure for the desired lasing wavelength (λ). Subsequently, electron-beam lithography (EBL), combined with reactive ion etching (RIE), is employed to pattern the substrate for the NPC formation. This is followed by the synthesis of NPC using molecular beam epitaxy (MBE). Depending on the intended lasing wavelength λ, different gain medium will be chosen (i.e., AlGaN, GaN, or InGaN). Finally, the electrically injected devices are fabricated, which primarily involves electrode fabrication.

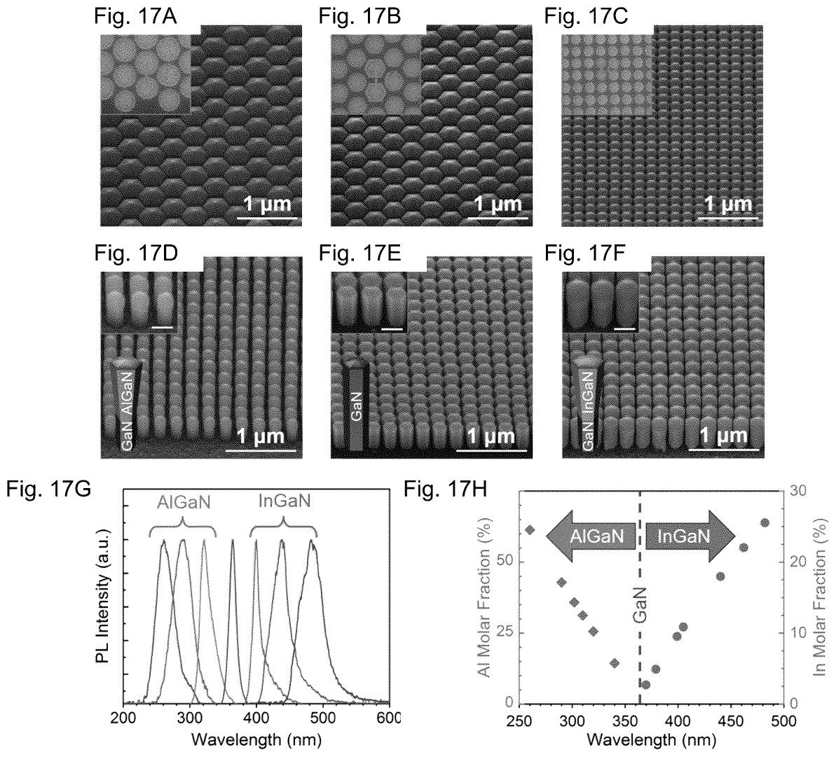

As the pattern control is critical for such lasers, focus is put on pattern control first. Insets of FIGS. 17A to 17C show scanning electron microscope (SEM) images of different patterns on GaN on sapphire template (top view), including triangular lattice with circular openings, triangular lattice with hexagonal-shaped openings, and square lattice with circular openings, with center-to-center spacing (lattice constant) “a” labeled. It is seen that both the lattice and the opening shape can be well controlled. This paves the ground for the formation of NPC cavities with desired lasing wavelengths. Experimentally, the patterning process was performed on Si-doped n-GaN on sapphire substrate. First, using e-beam evaporator, a thin (10 nm) Ti layer was deposited as a mask on the substrate. Next, using EBL and RIE, nanohole arrays in different arrangements (square and hexagonal lattices) and shapes (circular and hexagonal) were further created.

The growth of GaN nanowire arrays on such patterned substrates (i.e., selective area epitaxy, SAE) is further carried out by radio frequency (RF) plasma-assisted molecular beam epitaxy (PAMBE). Prior to loading the patterned substrates into MBE growth chamber, standard solvent cleaning was performed. The nanowire growth followed by a two-step process. First, Ti-patterned substrate was nitrided at 400° C. in the MBE growth chamber to prevent Ti mask degradation at elevated temperatures during the growth. This was followed by the growth of GaN nanowires as the second step. The growth conditions included a substrate temperature (T_{sub}) of 840° C., a nitrogen flow rate of 0.6 sccm, and a Ga beam equivalent pressure (BEP) of 2.5×10⁻⁷ Torr. The tilted-view SEM images in FIGS. 17A to 17C show GaN nanowires, revealing highly ordered nanowire arrays, which correlates to the designed patterns very well. It is also noted that, due to the lateral growth, similar top and sidewall surface morphologies are obtained for nanowires on triangular lattices with circular openings and hexagonal-shaped opening.

Next, to achieve desired lasing wavelengths in a wide spectral range, obtaining gain medium that can support a wide range of photon energies is necessary, which requires materials to have a wide range of optical bandgap energies. As such, it is demonstrated that such a requirement can be fulfilled using MBE grown III-nitride nanowires. FIGS. 17D to 17F show the SEM images of AlGaN nanowires, GaN nanowires, and InGaN nanowires, grown on patterned substrates with a square lattice. For AlGaN and InGaN nanowires, GaN nanowires were used as the template. The growth conditions for the AlGaN segment included a T_{sub} ranging from 870° C. to 920° C., a nitrogen flow rate of 0.6 sccm, and Al and Ga BEPs in the ranges of 2-5.5×10⁻⁸ and 0.4-2.5×10⁻⁷ Torr, respectively; whereas for the InGaN segment, T_{sub} was in the range of 570-650° C., the nitrogen flow rate was 0.6 sccm, and In and Ga BEPs were 0.3-2×10⁻⁷ and 1-2.5×10⁻⁸ Torr, respectively. It is seen that for both AlGaN and InGaN nanowires, the top segment is noticeably larger compared to the GaN nanowire root, due to the enhanced lateral growth during the growth of AlGaN or InGaN segments.

FIG. 17G shows the room temperature (RT) photoluminescence (PL) spectra of such AlGaN and InGaN nanowires with different Al and In contents. In this regard, the measurements were performed using a 213 nm pulsed laser with a pulse width of 7 ns. The laser light was focused onto the sample surface through a focus lens with the spot size of around 9×10⁻⁴ cm², and the emitted light was also collected from the sample surface using a focus lens, which was further coupled to an optical fiber and an UV-Vis spectrometer. It is seen that light emission from 250 nm to 500 nm is obtained. The correlated molar fraction of Al and In for such AlGaN and InGaN nanowires is shown in FIG. 17H, with Al molar fraction up to 62% and In molar fraction up to 26%. Here, the molar fraction was estimated by Vegard's law using the RTPL spectra. At this point, it should be noted, nonetheless, that in principle, a broader spectral range of light emission is achievable with further increasing Al or In contents.

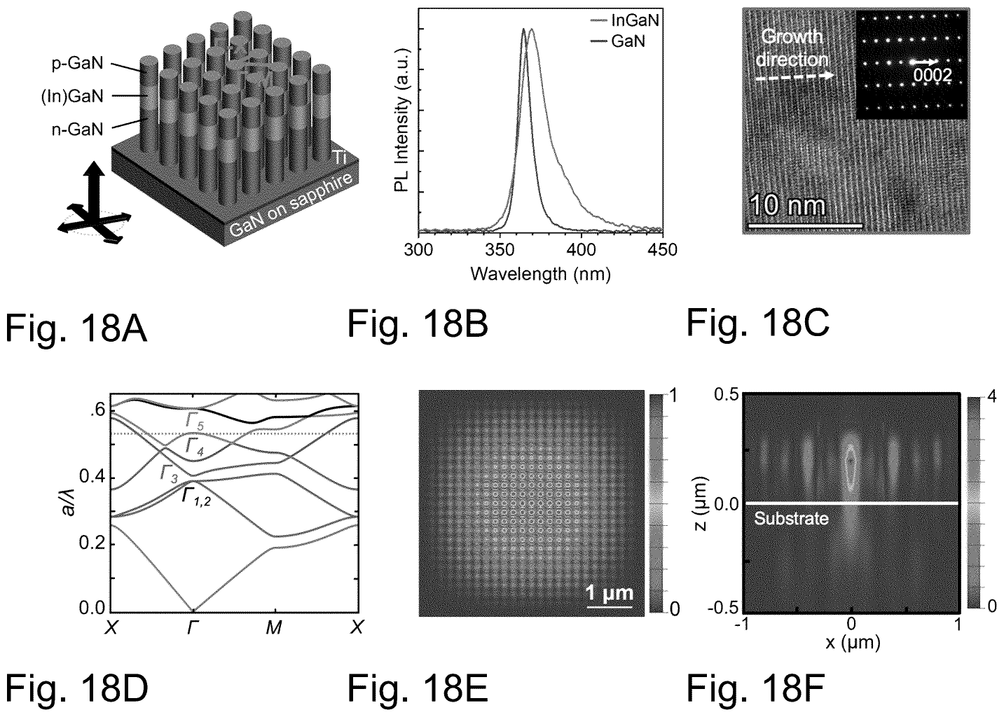

With achieving broadly tunable gain spectra SE lasing using such nanowire arrays under optical excitation is further demonstrated. SE lasing in the UV range is focused, as it remains a challenge today for SE lasing in the UV range. In this regard, both GaN and low In content InGaN were used as the gain medium, which provides the flexibility in the design of achieving lasing in the near UV range. FIG. 18A illustrates the structure of GaN or InGaN nanowire arrays that are intended to be used for NPC. Note that both the bottom and top are electrically doped for electrical current injection purpose (to be described later). FIG. 18B illustrates the RTPL spectrum of the low In content InGaN that is used for the InGaN NPC, together with the RTPL spectrum of GaN for a comparison purpose. It is seen that compared to the GaN RTPL peak at 364 nm, the low In content InGaN peak is shifted to around 370 nm, which correlates to 2-3 mol % In incorporation in the InGaN. The nanowire arrays possess excellent crystalline quality. For example, FIG. 18C shows an exemplary high resolution transmission electron microscopy (TEM) image of an individual GaN nanowire that constitutes the GaN nanowire arrays. Crystalline planes are clearly seen, suggesting excellent crystalline quality. The inset of FIG. 18C shows a selected area electron diffraction (SAED) image, which further confirms the excellent crystalline quality. For the TEM study, the sample was prepared by focus ion beam (FIB), and the TEM study was carried out by Thermo Scientific Talos F200X G2 STEM.

Lasing cavity design is subsequently carried out to obtain suitable lattice constant a and nanowire diameter d_{NW} that can support SE lasing in the near UV range. The lasing exploits band edge mode at Γ point in a square lattice, which not only produces optical gain due to the formation of slow light, but also diffracts the light to emit from the top surface. This is also schematically shown in FIG. 18A. Also shown in FIG. 18A is the representative in-plane light propagation directions (Γ-X and Γ-M) for a square lattice. FIG. 18D shows the calculated 2-dimensional (2D) transverse-magnetic (TM) photonic band structure related to the low In content InGaN NPC using 2D space and wave optics package in COMSOL Multiphysics, with a=200 nm and d_{NW}=187 nm. In this simulation, eigenfrequency study and k-vector sweep across the irreducible Brillion zone (BZ) were performed to compute the bands. It is seen that the reduced frequency a/λ aligns very well with the band edge at 0.529 at the Γ point, correlating to a slow light with a wavelength of around 378 nm.

FIGS. 18E and 18F further show the in-plane and out of plane electric field intensity (|E|²) calculated by three-dimensional (3D) finite difference time-domain (FDTD) using the same design parameters, respectively. In the FDTD simulation, the nanowires were arranged in a square lattice, and a TM dipole source with a central wavelength of 378 nm (correlating to the reduced frequency) was positioned in the center of the NPC. The lateral dimension for the in-plane electric field simulation was 5 μm×5 μm, and 12 steep-angle perfect matched layers (PML) surrounding the simulated structure was used to annihilate all the incoming waves. It is seen that a strong mode profile is present inside the NPC (FIG. 18E), whereas the optical field can also be confined in the vertical direction (FIG. 18F). These results suggest that if having low In content InGaN nanowire arrays with a of 200 nm and d_{NW} of 187 nm, an InGaN NPC, which can support SE lasing in the UV range, could be formed.

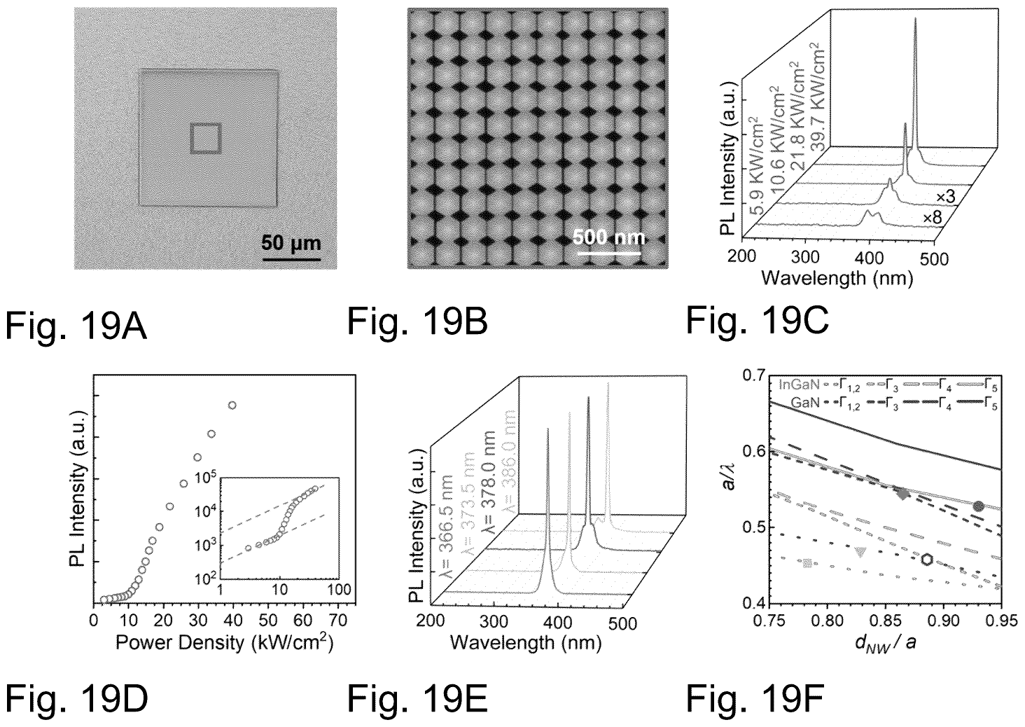

In this regard, intensive MBE growth and substrate patterning runs were performed in order to realize the low In content InGaN nanowire arrays or GaN nanowire arrays with the intended design parameters, as MBE growth parameters and pattern feature sizes (lattice constant a and nanohole diameter d) are coupled. FIG. 19A shows an optical image of the low In content InGaN NPC with a size of 120 μm×120 μm. FIG. 19B provides a high-magnification top-view SEM image of the nanowires forming the epi-NPC (from the region denoted in FIG. 19A). Optical pumping was subsequently carried out with the 213 nm pulse laser using the RTPL setup as afore described. FIG. 19C shows the light emission spectra under different excitation powers. It is seen that under the low excitation power, the light emission is dominated by the light emission related to the band edge emission of InGaN. The peak at around 387 nm could be related to p-GaN. As the optical excitation power increases, a peak at around 378 nm emerges, corresponding to the slow light mode. The light-in light-out (L-L) curve as a function of the excitation power is further shown in FIG. 19D, revealing a clear threshold of below 10 kW/cm². The inset of FIG. 19D shows the L-L curve in a logarithmic scale, and the S-shape confirms the achievement of lasing.

By altering design parameters as well as using GaN as the gain medium, optically pumped lasing at various UV wavelengths can also be obtained, as shown in FIG. 19E. Nonetheless, it is noted that the spectral linewidth remains relatively broad for these optically pumped SE UV lasers, which is mainly limited by the optical setup: The focal lens has a large numerical aperture (˜0.5), and the portable CCD monochromator has a resolution of 1 nm. In addition, in the present experiments, a pulsed laser was used, and the pulse-to-pulse energy variation could also contribute to the relatively broad linewidth.

FIG. 19F further shows the wavelength (reduced frequency: a/λ) and designed parameters (a/d_{NW}) relations for the band edges at Γ_{1,2}, Γ₃, Γ₄, and Γ₅ points (labeled in FIG. 18B) for GaN and low In content InGaN epi-NPCs. The curves are from COMSOL simulation with method described earlier, in which the photonic band structure is obtained from the parameters a, d_{NW}, and the gain medium (GaN or InGaN) refractive index. The filled symbols are experimental data under optical pumping (corresponding to FIG. 19E) and the open symbol is the experimental data under direct electrical injection (to be described). It is seen that by combining GaN and low In content InGaN gain medium, it offers a wide range of design that can support lasing in the UV range, which essentially makes it possible to obtain SE UV lasing with lasing wavelengths on demand.

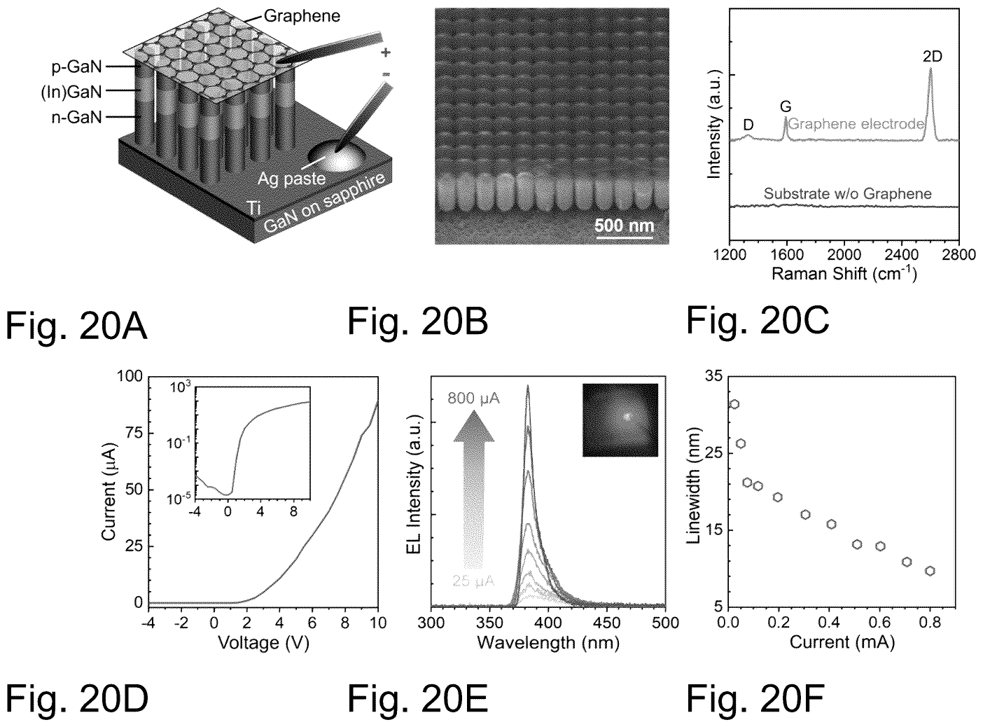

Electrically injected devices are fabricated in the end. In this regard, graphene was used as the p-contact on top of the epi-NPC, and colloidal Ag paste was applied to the conductive n-GaN substrate as the n-contact. The device schematic is shown in FIG. 20A. Two tungsten probes are also shown for electrical current injection. Here, it is worthwhile to note that no graphene etching was performed. Due to the nanowire height difference, as well as the difference in graphene stickiness to planar n-GaN and Ti mask surfaces and nanowire arrays, the graphene breaks naturally to form contact pads. The graphene transfer process was fine-tuned by intensive runs of experiments to optimize the sticking of graphene to the epi-NPC. Overall, the steps are as follows. First, commercial monolayer graphene on a copper (Cu) foil coated with polymethyl methacrylate (PMMA) was etched using a chloride-based etchant, followed by rinsing with de-ionized (DI) water to remove any residues and transferring graphene/PMMA to the top of the NPC structure. The sample with graphene/PMMA was then air-dried and subsequently placed in an oven to remove any water residual. Finally, PMMA was removed using acetone, followed by rinsing with isopropanol alcohol (IPA) and DI water, and dried with N₂ gas.

FIG. 20B shows an SEM image of the graphene electrode, highlighting the cross-section of the device covered with the graphene top electrode and the uniformity of the graphene coverage. Due to the significantly improved nanowire size, especially the height uniformity, the graphene coverage is significantly improved compared to at least some previous studies. The Raman spectra were further measured from the graphene electrode and the substrate without graphene using a 785 nm laser focused with a 50× objective onto the device top surface, as shown in FIG. 20C. It is seen that, compared to the substrate, typical graphene peaks D, G, and 2D at 1334, 1591, and 2601 cm⁻¹, respectively, are measured, confirming the successful transfer of graphene. In addition, the narrow 2D peak, together with 2D/G peak ratio being greater than 2, indicates a single layer graphene. The slight shift of the 2D peak could be attributed to the strain of graphene.

The I-V characteristics of such devices are shown in FIG. 20D. The electrical injection to the devices was realized by a Keithley 2400 source meter under a continuous-wave (CW) biasing mode. It is seen that excellent diode behavior is measured, with a turn-on voltage of around 3 V, a negligible leakage current, and a large rectification ratio (>10⁴) at ±4 V. The RT electroluminescence (EL) spectra under different injection currents are shown in FIG. 20E, with the inset showing a photo of the light emission. The EL was collected from the device top surface with an optical fiber, which was coupled to an UV-Vis spectrometer. It is seen that as the injection current increases, a strong emission at 382 nm is measured, and the spectra get narrower. This trend is more clearly shown in FIG. 20F: As the injection current increases, the linewidth reduces from around 31 nm to less than 10 nm, suggesting the presence of a light amplification at this wavelength. This light emission wavelength is indicated by the open symbol in FIG. 19F.

This achievement of light amplification in the UV range under a direct current injection at a low injection level (˜6 A/cm²) promises lasing at higher injection current density. In the present example, although significantly improved graphene electrodes were achieved compared to previous examples, graphene adhesion issue is still present in some embodiments, which can limit the further increase of the injection current density. In addition, the inherent graphene crack network (more discussions on graphene electrode can be found in Supporting Information), due to the nature of graphene also limits the current injection. Nevertheless, the present example paves a viable path toward not only electrically injected SE UV lasers, but more importantly, SE lasers with on demand lasing wavelength using a single material platform, spanning from deep UV to near-infrared; and the issues related to graphene can be potentially addressed utilizing conventional nanowire device fabrication process.

In summary, this example investigated SE lasers using low In content InGaN (including GaN) epi-NPCs. First, through meticulous control of the patterning process and growth conditions, nanowire arrays with tunable optical bandgaps from 250 nm to 500 nm are demonstrated. Subsequently, by using low In content InGaN and GaN gain medium as the active region and exploiting NPCs with a square lattice, optically pumped SE UV lasers at different lasing wavelengths are achieved with ultralow lasing threshold, drastically lower compared to conventional UV VCSELs at similar wavelengths. Lastly, using graphene electrode, electrically injected devices are fabricated, which exhibit excellent diode behavior with a rectification ratio of >10⁴ at ±4 V and amplified spontaneous emission in the UV range. This example not only represents a leap forward toward electrically injected SE UV lasers, but also provides a viable path for SE lasers with lasing wavelength on demand, potentially from 200 nm to 2 μm leveraging the ultrawide optical bandgap tunability of III-nitrides, as well as the excellent controllability of nanowire arrays.

Based on this example, it was found that one could manufacture a surface-emitting lasing device having a desired lasing wavelength by modifying the manufacturing parameters based on the desired lasing wavelength. For instance, there is described a method for manufacturing a surface-emitting lasing device having an array of III-nitride nanowires. The method has a step of selecting a lasing wavelength ranging between about 200 nm and 2 μm. It is understood that the lasing wavelength characterizing lasing emission occurring upon pumping of the surface-emitting lasing device. The pumping can be optical or electrical, depending on the embodiment. In the case of electrical pumping, a graphene electrode can cover the tips of the group III-nitride nanowires, for instance. The method has a step of determining manufacturing parameters based on the lasing wavelength. In some embodiments, the manufacturing parameters can include, but are not limited to, a semiconductor material composition, composition distribution along the nanowire lengths, a lattice constant defining the array, a nanowire geometry and a nanowire dimension (e.g., nanowire diameter). The method includes a step of forming a growth mask onto an a base layer of a substrate. As can be understood, the growth mask having a plurality of apertures sized and shaped according to the lattice constant, the nanowire geometry and the nanowire dimension. The method includes, while heating the substrate at a given surface temperature (which can vary based on the material composition of the nanowires), directing semiconductor material molecules according to the semiconductor material composition towards the selective area growth mask. It is intended that the heating and the directing selectively grow the III-nitride nanowires of the array at corresponding ones of the plurality of apertures.

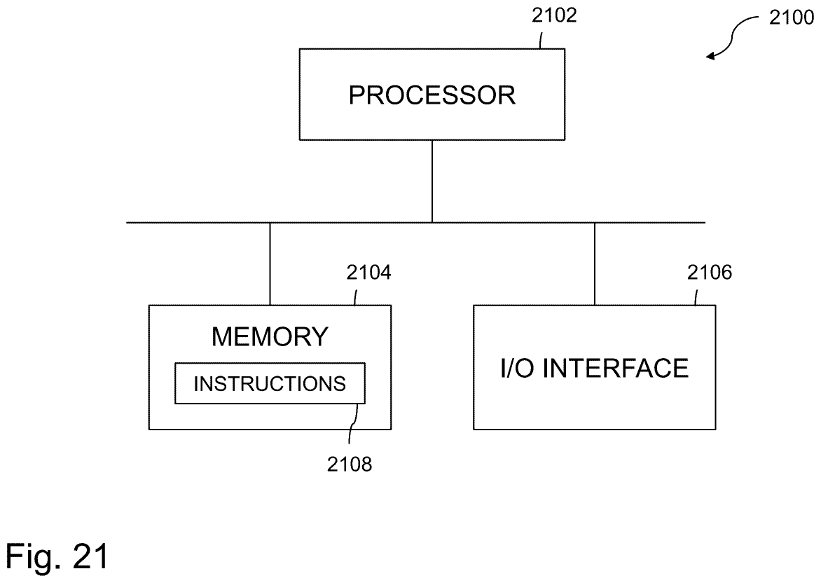

Such a method can be partly or wholly performed using a controller. The controller can be provided as a combination of hardware and software components. The hardware components can be implemented in the form of a computer 2100, an example of which is described with reference to FIG. 21. Moreover, the software components of the controller can be implemented in the form of one or more software applications.

Referring to FIG. 21, the computer 2100 can have a processor 2102, a memory 2104, and I/O interface 2106. Instructions 2108 for running the one or more software applications can be stored on the memory 2104 and accessible by the processor 2102.

The processor 2102 can be, for example, a general-purpose microprocessor or microcontroller, a digital signal processing (DSP) processor, an integrated circuit, a field programmable gate array (FPGA), a reconfigurable processor, a programmable read-only memory (PROM), or any combination thereof.

The memory 2104 can include a suitable combination of any type of computer-readable memory that is located either internally or externally such as, for example, random-access memory (RAM), read-only memory (ROM), compact disc read-only memory (CDROM), electro-optical memory, magneto-optical memory, erasable programmable read-only memory (EPROM), and electrically-erasable programmable read-only memory (EEPROM), Ferroelectric RAM (FRAM) or the like.

Each I/O interface 2106 enables the controller to interconnect with one or more input devices, such a temperature sensor, or with one or more output devices such as a nitrogen source control module, a gallium source control module, a graphical user interface, a memory system and/or a telecommunications network.

Each I/O interface control module 2106 enables the controller to communicate with other components, to exchange data with other components, to access and connect to network resources, to server applications, and perform other computing applications by connecting to a network (or multiple networks) capable of carrying data including the Internet, Ethernet, plain old telephone service (POTS) line, public switch telephone network (PSTN), integrated services digital network (ISDN), digital subscriber line (DSL), coaxial cable, fiber optics, satellite, mobile, wireless (e.g. Wi-Fi, WiMAX), SS7 signaling network, fixed line, local area network, wide area network, and others, including any combination of these.

The computer 2100 and the software layers described above are meant to be examples only. Other suitable embodiments of the controller can also be provided, as it will be apparent to the skilled reader.

It will be understood that a computing device 2102 can perform functions or processes via hardware or a combination of both hardware and software. For example, hardware can include logic gates included as part of a silicon chip of a processor. Software (e.g. application, process) can be in the form of data such as computer-readable instructions stored in a non-transitory computer-readable memory accessible by one or more processing units. With respect to a computer or a processing unit, the expression “configured to” relates to the presence of hardware or a combination of hardware and software which is operable to perform the associated functions.

As can be understood, the examples described above and illustrated are intended to be exemplary only. The scope is indicated by the appended claims.

What is claimed is:

1. A method of manufacturing an array of gallium nitride (GaN) nanowires via selective area growth, the method comprising:
mounting a substrate to a substrate holder face exposed within a growth cavity, the substrate having a base layer and a selective area growth mask covering the base layer, the selective area growth mask having a plurality of apertures spaced apart from one another and exposing the base layer thereunder;
while heating the growth cavity at a given surface temperature, the given surface temperature ranging between about 650° C. and 750° C. when measured on a side of the substrate holder face to which the substrate is mounted, directing gallium (Ga) and nitrogen (N) atoms towards the selective area growth mask at a gallium growth rate below about 10 nm/min and a nitrogen growth rate below 5 nm/min, respectively, said heating and said directing selectively growing the GaN nanowires of the array at corresponding ones of the plurality of apertures.

2. The method of claim 1 wherein the given surface temperature preferably ranges between about 710° C. and 730° C., and most preferably is about 720° C.

3. The method of claim 1 wherein the gallium growth rate ranges between 1 and 10 nm/min, preferably between 2 and 8 nm/min and most preferably between 1.5 and 5 nm/min.

4. The method of claim 1 wherein the nitrogen growth rate ranges between 2 and 5 nm/min, preferably between 3 and 4 nm/min.

5. The method of claim 1 wherein the plurality of GaN nanowires have at least one of a uniform geometry, a uniform length, a uniform cross-sectional shape, a uniform thickness and a uniform tip shape.

6. The method of claim 1 wherein the GaN nanowires have a base at a corresponding one of the plurality of apertures, an elongated body extending transversally to the substrate and a tip, at least some of the tips of the plurality of GaN nanowires ending in a planar top facet parallel to the substrate.

7. The method of claim 6 wherein the at least some of the tips of the plurality of GaN nanowires end in a uniform wurtzite-like structure.

8. The method of claim 1 wherein the plurality of apertures of the selective area growth mask have a hexagonal shape.

9. The method of claim 1 wherein the selective area growth mask includes one of silicon nitride, titanium, and silicon dioxide, and wherein the base layer includes a GaN-based layer.

10. A semiconductor substrate comprising:
a base layer;
a mask layer covering the base layer, the mask layer having a plurality of apertures spaced apart from one another;
a plurality of group III-nitride nanowires extending away from the plurality of apertures, the group III-nitride nanowires having a base at a corresponding one of the plurality of apertures, an elongated body extending transversally to the base layer and a tip, the plurality of group III-nitride nanowires having at least one of a uniform geometry, a uniform length, a uniform cross-sectional shape, a uniform thickness and a uniform tip shape.

11. The semiconductor substrate of claim 10 wherein at least some of the tips of the plurality of group III-nitride nanowires end in a planar top facet parallel to the substrate.

12. The semiconductor substrate of claim 11 wherein at least some of the tips of the plurality of group III-nitride nanowires end in a uniform wurtzite-like structure.

13. The semiconductor substrate of claim 10 wherein the mask layer includes one of silicon nitride, titanium, and silicon dioxide.

14. The semiconductor substrate of claim 10 wherein the semiconductor substrate is part of an optical emitting device which when the plurality of group III-nitride nanowires are electrically pumped using a current greater than a current threshold, the optical emitting device generates a laser signal generally perpendicularly to the semiconductor substrate.

15. The semiconductor substrate of claim 14 further comprising a graphene electrode electrically connected to the tips of the plurality of group III-nitride nanowires, the current applied at least partially via the graphene electrode.

16. The semiconductor substrate of claim 15 wherein the laser signal includes optical energy distributed within an ultraviolet range of the electromagnetic spectrum.

17. The semiconductor substrate of claim 14 wherein the optical emitting device has a lasing threshold power density threshold below 10 kW/cm².

18. The semiconductor substrate of claim 14 wherein the group III-nitride nanowires include one or more of the following group III-nitride semiconductor materials: gallium nitride (GaN), aluminum gallium nitride (AlGaN), and indium gallium nitride (InGaN).

19. A method of manufacturing a surface-emitting lasing device having an array of III-nitride nanowires, the method comprising:
selecting a lasing wavelength ranging between about 200 nm and 2 μm, the lasing wavelength characterizing lasing emission occurring upon pumping of the surface-emitting lasing device;
determining manufacturing parameters based on the lasing wavelength, the manufacturing parameters including: a semiconductor material composition, a lattice constant defining the array, a nanowire geometry and a nanowire dimension;
forming a growth mask onto an a base layer of a substrate, the growth mask having a plurality of apertures sized and shaped according to the lattice constant, the nanowire geometry and the nanowire dimension; and
while heating the substrate at a given surface temperature, directing semiconductor material molecules according to the semiconductor material composition towards the selective area growth mask, said heating and said directing selectively growing the III-nitride nanowires of the array at corresponding ones of the plurality of apertures.

20. The method of claim 19 wherein the group III-nitride nanowires include one or more of the following group III-nitride semiconductor materials: gallium nitride (GaN), aluminum gallium nitride (AlGaN), and indium gallium nitride (InGaN).
